(19) United States
(12) Patent Application Publication
(10) Pub. No.: US 2024/0324188 A1
(43) Pub. Date: Sep. 26, 2024

(54) INTEGRATED CIRCUIT DEVICE AND METHOD OF MANUFACTURING THE SAME

(71) Applicant: Samsung Electronics Co., Ltd., Suwon-si (KR)

(72) Inventors: Kangin KIM, Suwon-si (KR); Sangbin AHN, Suwon-si (KR); Youngseung CHO, Suwon-si (KR); Kyounghwan KIM, Suwon-si (KR)

(73) Assignee: Samsung Electronics Co., Ltd., Suwon-si (KR)

(21) Appl. No.: 18/606,436

(22) Filed: Mar. 15, 2024

(30) Foreign Application Priority Data
Mar. 24, 2023 (KR) 10-2023-0039313

(51) Int. Cl. H10B 12/00; H01L 29/423; H01L 29/66; H01L 29/78

(52) U.S. Cl. CPC H10B 12/488; H01L 29/4236; H01L 29/6681; H01L 29/7851; H10B 12/36

(57) ABSTRACT

An integrated circuit device includes a substrate including a plurality of active areas and a plurality of dummy active areas, and defines a plurality of word line trenches that cross the plurality of active areas and the plurality of dummy active area, extend in a first horizontal direction in parallel with each other and have an active side bottom surface exposing the plurality of active areas and a dummy side bottom surface exposing the plurality of dummy active areas. The dummy side bottom surface is at a lower vertical level than the active side bottom surface.

### CROSS-REFERENCE TO RELATED APPLICATION

This application is based on and claims priority under 35 U.S.C. § 119 to Korean Patent Application Nos 10-2023-0039313, filed on Mar. 24, 2023 in the Korean Intellectual Property Office, the disclosure of which is incorporated by reference herein in its entirety.

### BACKGROUND

Various example embodiments relate to an integrated circuit device and/or a method of manufacturing the integrated circuit device, and more particularly, to an integrated circuit device including word lines buried in a substrate and/or a method of manufacturing the integrated circuit device.

Recently, as the degree of integration of integrated circuit devices has gradually increased, the structure of integrated circuit devices with a buried channel array transistor (BCAT) in the form of a plurality of word lines buried in a substrate has been proposed. Accordingly, various studies are being conducted to improve and stabilize the operation and reliability of the BCAT.

### SUMMARY

Various example embodiments provide an integrated circuit device with improved reliability.

Alternatively or additionally, various example embodiments provide a method of manufacturing a semiconductor device with improved reliability.

According to some example embodiments, there is provided an integrated circuit device. An integrated circuit device includes a substrate including a plurality of active areas and a plurality of dummy active areas with a plurality of word line trenches that cross the plurality of active areas and the plurality of dummy active area, extend in a first horizontal direction in parallel with each other and have an active side bottom surface exposing the plurality of active areas and a dummy side bottom surface exposing the plurality of dummy active areas. The dummy side bottom surfaces is at a lower vertical level than the active side bottom surface.

Alternatively or additionally according to various example embodiments, there is provided an integrated circuit device. The integrated circuit device includes a substrate including a plurality of fin-type active areas and a plurality of fin-type dummy active areas that are defined by a device isolation layer. The integrated circuit defines a plurality of word line trenches that cross the plurality of fin-type active areas and the plurality of fin-type dummy active areas and extend in a first horizontal direction in parallel with each other. The plurality of fin-type active areas include active side saddle portions exposed on bottom surfaces of the plurality of word line trenches. The plurality of fin-type dummy active areas include dummy side saddle portions exposed on bottom surfaces of the plurality of word line trenches. An upper surface of the dummy side saddle portions is at a lower vertical level than an upper surface of the active side saddle portions.

According to some example embodiments, there is provided an integrated circuit device. The integrated circuit device includes a substrate including a plurality of dummy active areas and a plurality of dummy active areas that are defined by a device isolation layer. The integrated circuit defines a plurality of word line trenches cross the plurality of active areas and the plurality of dummy active area, extend in a first horizontal direction in parallel with each other, and have an active side bottom surface exposing the plurality of active areas and a dummy side bottom surface exposing the plurality of dummy active areas at a lower vertical level than the active side bottom surface. The integrated circuit includes a plurality of gate electrodes respectively arranged in the plurality of word line trenches and extending in the first horizontal direction in the plurality of active areas and the plurality of dummy active areas. A portion of the plurality of gate electrodes that at least partly overlaps the plurality of active areas has an active side width in a second horizontal direction perpendicular to the first horizontal direction. A portion of the plurality of gate electrodes that overlaps the plurality of dummy active areas has a dummy side width in the second horizontal direction. The dummy side width is greater than the active side width.

### BRIEF DESCRIPTION OF THE DRAWINGS

Embodiments will be more clearly understood from the following detailed description taken in conjunction with the accompanying drawings in which:

FIG. 1 is a layout diagram of a schematic configuration of an integrated circuit device, according to some example embodiments;

FIG. 2A is an enlarged layout diagram of a region EX1 in FIG. 1;

FIG. 2B is a cross-sectional view taken along line X1-X1′ in FIG. 2A;

FIG. 2C is an enlarged cross-sectional view of a region indicated by EX3 in FIG. 2A;

FIG. 2D is a cross-sectional view taken along line Y1-Y1′ in FIG. 2A;

FIG. 2E is an enlarged layout diagram of a region EX2 in FIG. 2A;

FIG. 3A is a layout diagram illustrating a schematic configuration of a portion of an integrated circuit device according to some example embodiments, corresponding to FIG. 2A;

FIG. 3B is a cross-sectional view taken along line Y2-Y2′ in FIG. 3A;

FIG. 3C is an enlarged cross-sectional view of a region EX4 in FIG. 3B;

FIG. 4 is a layout diagram illustrating a schematic configuration of an integrated circuit device according to some example embodiments;

FIG. 5A is a cross-sectional view taken along line Y3-Y3′ in FIG. 4, with respect to which a method of manufacturing an integrated circuit device, according to some example embodiments, is described;

FIG. 5B is a cross-sectional view taken along line Y4-Y4′ in FIG. 4, with respect to which a method of manufacturing an integrated circuit device, according to some example embodiments, is described; and

FIGS. 6A to 6M are cross-sectional views illustrating cross-sections of a cell array area and a boundary area according to process sequence of a method of manufacturing an integrated circuit device, according to embodiments.

### DETAILED DESCRIPTION OF VARIOUS EXAMPLE EMBODIMENTS

Hereinafter, various example embodiments are described in detail with reference to the accompanying drawings. Identical reference numerals are used for the same components in the drawings, and a duplicate description thereof will be omitted.

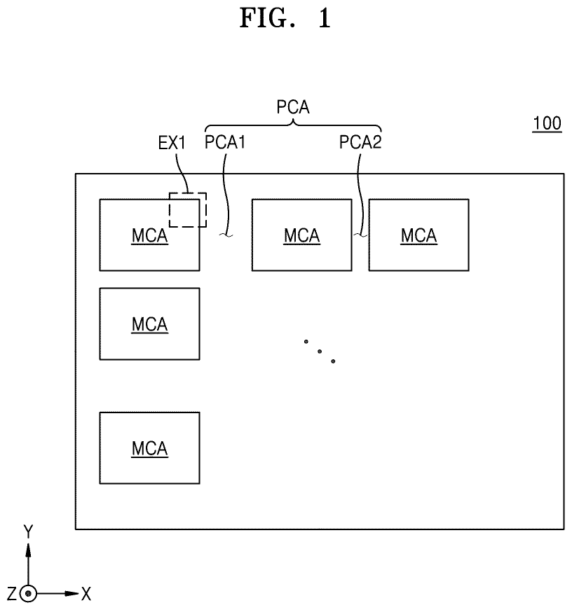

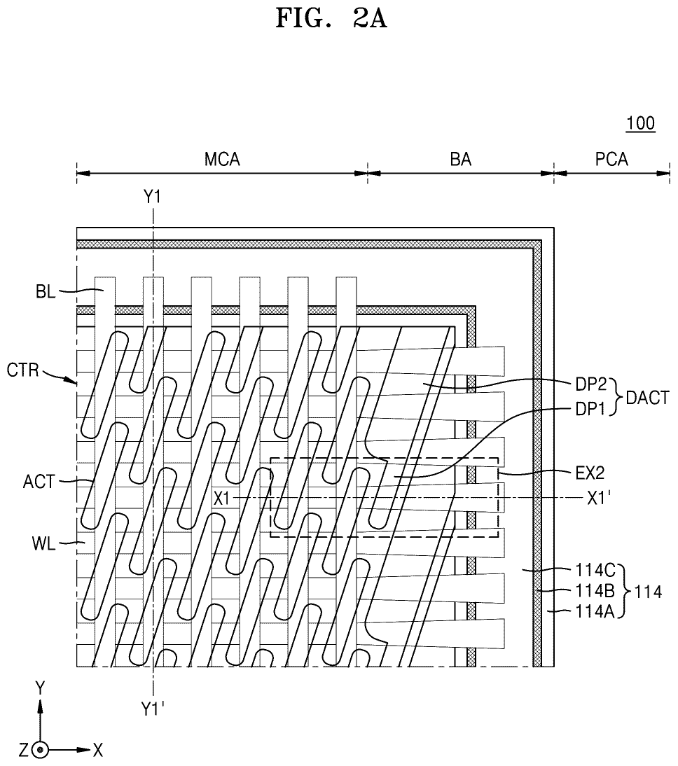

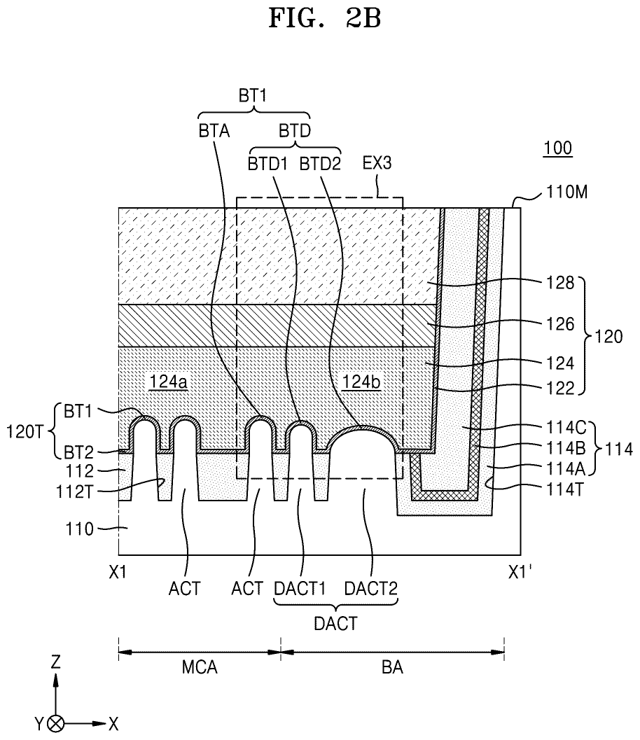

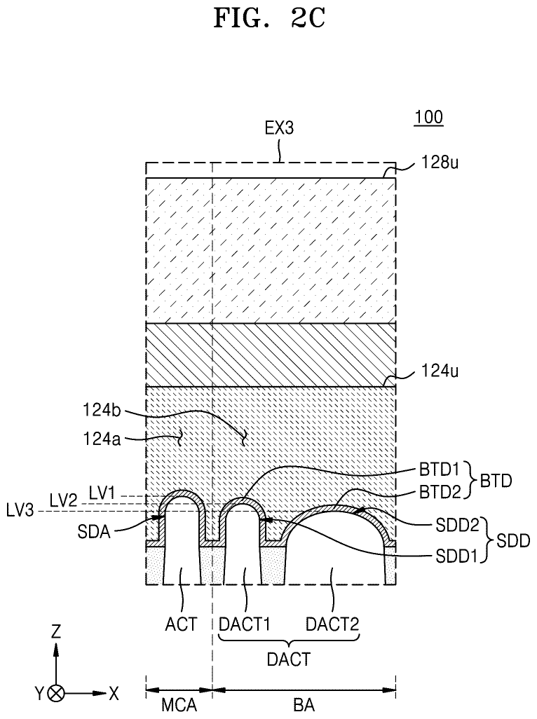

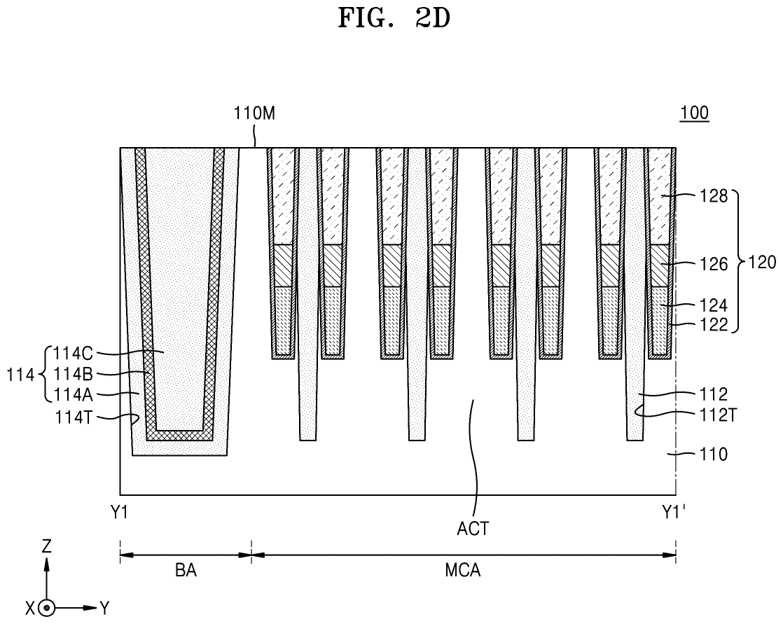

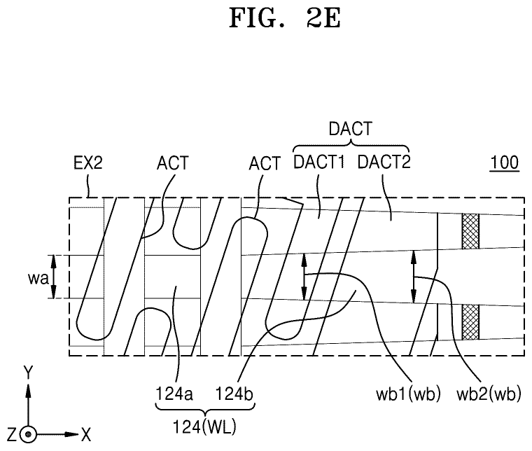

FIG. 1 is a layout diagram of a schematic configuration of an integrated circuit device 100, according to some example embodiments. FIG. 2A is an enlarged layout diagram of a region EX1 in FIG. 1. FIG. 2B is a cross-sectional view taken along line X1-X1′ in FIG. 2A. FIG. 2C is an enlarged cross-sectional view of a region indicated by EX3 in FIG. 2A. FIG. 2D is a cross-sectional view taken along line Y1-Y1′ in FIG. 2A. FIG. 2E is an enlarged layout diagram of a region EX2 in FIG. 2A.

Referring to FIGS. 1 and 2A through 2E, the integrated circuit device 100 may include a semiconductor substrate 110 including a cell array area MCA, a periphery circuit area PCA, and a boundary area BA between the cell array area MCA and the periphery circuit area PCA.

In some example embodiments, the cell array area MCA may include a cell array area of a dynamic random access memory (DRAM) device and the periphery circuit area PCA may include a core area or a periphery circuit area of the DRAM device. For example, the cell array area MCA may include a cell transistor CTR and a memory element such as a capacitor structure (not illustrated) connected thereto. Alternatively or additionally, the memory element may be or include a memristor and/or a device having hysteresis properties.

In some example embodiments, the periphery circuit area PCA may include a periphery circuit transistor (not illustrated) for transmitting a signal and/or power to the cell transistor CTR included in the cell array area MCA. In some example embodiments, the periphery circuit transistor (not illustrated) may constitute various circuits, such as a command decoder, a control logic, an address buffer, a row decoder, a column decoder, a sense amplifier, and a data input/output circuit. In some example embodiments, the periphery circuit transistors may be planar and/or may be three-dimensional; example embodiments are not limited thereto.

In some example embodiments, the periphery circuit area PCA may include an area between two adjacent cell array areas MCA and may include a first periphery circuit area PCA1 with a relatively long horizontal distance between two adjacent cell array areas MCA and a second periphery circuit areas PCA2 with a relatively short horizontal distance between two adjacent cell array areas MCA. For example, the cell array area MCA may be apart from the first periphery circuit area PCA1 and/or the second periphery circuit area PCA2 with the boundary area BA therebetween.

According to some example embodiments, a device isolation trench 112T may be formed in the substrate 110, and a device isolation layer 112 may be arranged in the device isolation trench 112T. The device isolation trench 112T may be filled with the device isolation layer 112.

According to some example embodiments, in the cell array area MCA, a plurality of active areas ACT may be defined in the substrate 110 by the device isolation layer 112. According to some example embodiments, in the cell array area MCA, the plurality of active areas ACT may be arranged to have a long axis extending obliquely with respect to the first horizontal direction (X direction) and the second horizontal direction (Y direction) crossing the first horizontal direction (X direction). In some example embodiments, an angle between the X direction and the extension direction of the active areas ACT may be greater than 45 degrees; however, example embodiments are not limited thereto. According to some example embodiments, a plurality of active areas ACT may be disposed to be spaced apart from each other in the horizontal direction (X direction and/or Y direction).

According to some example embodiments, in the boundary area BA, a plurality of dummy active areas DACT may be defined in the substrate 110 by the device isolation layer 112. According to some example embodiments, the plurality of dummy active areas DACT may surround the plurality of active areas ACT in the cell array area MCA in a plan view and may be arranged apart from the plurality of active areas ACT. In various example embodiments, a dummy active area DACT may be an active area that is not electrically active during operation of the semiconductor device.

In some example embodiments, each of the plurality of dummy active areas DACT may include a first portion DP1 and a second portion DP2, which have different widths from each other in a plan view. For example, a width of the second portion DP2 in the first horizontal direction (X direction) may be greater than a width of the first portion DP1 in the first horizontal direction (X direction). For example, the width of the second portion DP2 in the first horizontal direction (X direction) may be greater than the width of each of the plurality of active areas ACT in the first horizontal direction (X direction).

Alternatively or additionally in some embodiments, each of the plurality of dummy active areas DACT may have a uniform horizontal width according to the extension direction. For example, the plurality of dummy active areas DACT may be arranged to have a long axis extending in a diagonal direction with respect to the first horizontal direction (X direction) and the second horizontal direction (Y direction). For example, the width in the first horizontal direction (X direction) of each of the plurality of dummy active areas DCAT may be similar to or the same as the width in the first horizontal direction (X direction) of each of the plurality of active areas ACT.

According to some example embodiments, the device isolation layer 112 may surround the plurality of active areas ACT and the plurality of dummy active areas DACT in the substrate 110. The vertical level of the bottom surface of the device isolation trench 112T may vary according to the horizontal width of the device isolation trench 112T. For example, as the horizontal width of the device isolation trench 112T increases, the vertical level of the bottom surface of the device isolation trench 112T may decrease. The term “vertical level” used in the inventive concept may mean the height in the vertical direction (Z direction or −Z direction) from a main surface 110M of the substrate 110. Additionally terms such as “above” and “below” may be terms relative to the vertical direction.

In some example embodiments, the substrate 110 may include silicon, for example, one or more of monocrystalline silicon, polycrystalline silicon, or amorphous silicon. Alternatively or additionally in some example embodiments, the substrate 110 may include at least one of germanium (Ge), silicon germanium (SiGe), silicon carbon (SiC), gallium arsenide (GaAs), indium arsenide (InAs), and indium phosphate (InP). In some example embodiments, the substrate 110 may include a conductive area, for example, a well doped with impurities and/or or a structure doped with impurities. In some example embodiments, the device isolation layer 112 may include an oxide layer, a nitride layer, or a combination thereof.

According to some example embodiments, a boundary structure 114 surrounding the plurality of active areas ACT and the plurality of dummy active areas DACT may be arranged in the boundary area BA. According to some example embodiments, the plurality of active areas ACT may be apart from the boundary structure 114 with the plurality of dummy active areas DACT therebetween. For example, the plurality of dummy active areas DACT may be respectively arranged between the plurality of active areas ACT and the boundary structure 114, which may improve the uniformity of the plurality of active areas ACT in the manufacturing process of the integrated circuit device 100 and may prevent or reduce the likelihood of and/or impact form a phenomenon in which the plurality of active areas ACT having a fin structure bend.

In some example embodiments, the plurality of dummy active areas DACT may be arranged in the second horizontal direction (Y direction) at first and second, or both sides of the cell array area MCA in the first horizontal direction (X direction). For example, the plurality of dummy active areas DACT may be arranged in the boundary area BA to surround two surfaces of both sides in the first horizontal direction (X direction) of the cell array area MCA. For example, the cell array area MCA may be apart from the boundary structure 114 in the first horizontal direction (X direction) with the plurality of dummy active areas DACT therebetween.

In FIG. 2A, the plurality of dummy active areas DACT are illustrated as being arranged in one column in the second horizontal direction (Y direction), but example embodiments are not limited thereto. For example, the plurality of dummy active areas DACT may also be arranged in two or more columns in the second horizontal direction (Y direction).

Alternatively or additionally in some example embodiments, the plurality of dummy active areas DACT may be arranged along the periphery of the cell array area MCA. For example, the plurality of dummy active areas DACT may be arranged to surround four sides of the cell array area MCA. For example, the plurality of dummy active areas DACT may be arranged in the first horizontal direction (X direction), surround both sides of the cell array area MCA in the second horizontal direction (Y direction), be arranged in the second horizontal direction (Y direction), and surround both sides of the cell array area MCA in the first horizontal direction (X direction). For example, the plurality of dummy active areas DACT may be arranged in two or more columns/rows in the second horizontal direction (Y direction)/first horizontal direction (X direction), respectively, and arranged to surround the plurality of active areas ACT. For example, the cell array area MCA may be apart from the boundary structure 114 with the plurality of dummy active areas DACT therebetween in the first horizontal direction (X direction) and/or the second horizontal direction (Y direction).

According to various example embodiments, a boundary trench 114T may be formed in the boundary area BA, and the boundary structure 114 may fill the boundary trench 114T. According to some example embodiments, in a plan view, the boundary structure 114 may be arranged to surround the plurality of active areas ACT and the plurality of dummy active areas DACT. According to some example embodiments, the boundary structure 114 may include a buried insulating layer 114A, an insulating liner 114B, and a gap-fill insulating layer 114C, which are arranged inside the boundary trench 114T.

The buried insulating layer 114A may be arranged, e.g., conformally arranged on the inner wall of the boundary trench 114T. In some example embodiments, the buried insulating layer 114A may include silicon oxide. The insulating liner 114B may be conformally arranged on the buried insulating layer 114A in the boundary trench 114T. In some example embodiments, the insulating liner 114B may include silicon nitride. The gap-fill insulating layer 114C may fill the inside of the boundary trench 114T on the insulating liner 114B. In some example embodiments, the gap-fill insulating layer 114C may include one or more of silicon oxide, such as tonen silazane (TOSZ), undoped silicate glass (USG), boro-phosphor silicate glass (BPSG), phosphor silicate glass (PSG), flowable oxide (FOX), plasma enhanced (PE) deposition of tetra-ethyl-ortho-silicate (TEOS) (PE-TEOS), and fluoride silicate glass (FSG).

Referring to FIG. 2A, a plurality of word lines WL may cross the plurality of active areas ACT and the plurality of dummy active areas DACT to extend in the first horizontal direction (X direction). For example, the plurality of word lines WL may be apart from each other in the second horizontal direction (Y direction) and may extend in parallel with each other. According to some example embodiments, a plurality of bit lines BL may extend in parallel with each other in the second horizontal direction (Y direction) on the plurality of word lines WL, respectively. The plurality of bit lines BL may be configured to be respectively and electrically connected to the plurality of active areas ACT. For example, the plurality of bit lines BL may be respectively connected to the plurality of active areas ACT via direct contacts (not illustrated). According to some example embodiments, a memory element such as a memristor and/or a capacitor structure (not illustrated) may be arranged on the plurality of bit lines BL. According to some example embodiments, the capacitor structure (not illustrated) may be connected to the plurality of active areas ACT via the contact structure (not illustrated) extending in the vertical direction (Z direction) between the plurality of bit lines BL. In FIGS. 2B through 2D, illustration of the plurality of bit lines BL in FIG. 2A is omitted for convenience.

According to some example embodiments, the substrate 110 may include or define a plurality of rows or word line trenches 120T extending in parallel with each other in the first horizontal direction (X direction), and a plurality of buried gate structures 120 may be respectively arranged within the plurality of word line trenches 120T. The plurality of word line trenches 120T may extend from the cell array area MCA into the boundary area BA, and ends of each of the plurality of buried gate structures 120 may overlap the plurality of dummy active areas DACT and boundary structures 114 in the vertical direction (Z direction) within the boundary area BA.

Each of the plurality of buried gate structures 120 may include a gate dielectric layer 122, a gate electrode 124, a conductive layer 126, and a capping insulating layer 128. The gate dielectric layer 122 may cover, e.g., conformally cover the inner wall of each of the plurality of word line trenches 120T (for example, the bottom and inner sides of each of the plurality of word line trenches 120T). The gate electrode 124 may at least partially fill each word line trench 120T on the gate dielectric layer 122, the conductive layer 126 may partially fill each word line trench 120T on the gate electrode 124, and the capping insulating layer 128 may cover the upper surface of the conductive layer 126 and fill the remaining portion of each word line trench 120T. According to some example embodiments, a plurality of gate electrodes 124 may be arranged at a vertical level lower than the main surface 110M of the substrate 110. According to some example embodiments, the plurality of gate dielectric layers 122 may be arranged to conformally cover the inner wall of each word line trench 120T and surround the gate electrode 124, the conductive layer 126, and the capping insulating layer 128. For example, the plurality of gate electrodes 124 may respectively correspond to the plurality of word lines WL illustrated in FIG. 2A.

In some example embodiments, the plurality of gate dielectric layers 122 may include one or more of a silicon oxide layer, a silicon nitride layer, a silicon oxynitride layer, an oxide-nitride-oxide (ONO) layer, or a high-k dielectric layer with a higher dielectric constant than the silicon oxide layer. In some example embodiments, the plurality of gate electrodes 124 may include Ti, TiN, TaN, W, WN, TiSiN, WSiN, or a combination thereof. In some example embodiments, a plurality of conductive layers 126 may include polysilicon, doped polysilicon, or a combination thereof. In some example embodiments, a plurality of capping insulating layer 128 may include a silicon oxide layer, a silicon nitride layer, a silicon oxynitride layer, or a combination thereof.

According to some example embodiments, a vertical level of a portion of the plurality of active areas ACT exposed through the bottom surface of the word line trench 120T and a vertical level of a portion of the plurality of dummy active areas DACT exposed through the bottom surface of the word line trench 120T may be higher than or above a vertical level of a portion of the device isolation layer 112 exposed through the bottom surface of the word line trench 120T. The bottom surface of the gate electrode 124 may have an uneven shape corresponding to the bottom surface profile of the word line trench 120T, and a saddle fin field effect transistor (FinFET) structure may be formed on the plurality of active areas ACT and the plurality of dummy active areas DACT. For example, each of the plurality of active areas ACT may include an active side saddle portion SDA, which is exposed on the bottom surface of each word line trench 120T and has a vertical level higher than that of the device isolation layer 112, and the plurality of dummy active areas DACT may include a dummy side saddle portion SDD, which is exposed on the bottom surface of each word line trench 120T and has a vertical level higher than that of the device isolation layer 112. For example, the active side saddle portion SDA may be a portion of the plurality of active areas ACT with a fin-type structure, which is arranged at a vertical level higher than that of the device isolation layer 112 at the bottom surface of the plurality of word line trenches 120T. For example, the dummy side saddle portion SDD may be a portion of the plurality of dummy active areas DACT with a fin-type structure, which is arranged at a vertical level higher than that of the device isolation layer 112 at the bottom surface of the plurality of word line trenches 120T and exposed.

According to some example embodiments, the word line trench 120T may include or have a first bottom surface BT1, where the plurality of active areas ACT and the plurality of dummy active areas DACT are exposed, and a second bottom surface BT2 where the device isolation layer 112 is exposed. For example, the first bottom surface BT1 and the second bottom surface BT2 may be covered by the gate dielectric layer 122, and the active side saddle portion SDA and the dummy side saddle portion SDD may face the bottom surface of the gate electrode 124 with the gate dielectric layer 122 therebetween. According to various example embodiments, the second bottom surface BT2 may be at a lower vertical level than the first bottom surface BT1.

According to various example embodiments, the first bottom surface BT1 may include an active side bottom surface BTA, where the plurality of active areas ACT are exposed, and a dummy side bottom surface BTD where the plurality of dummy active areas DACT are exposed. According to some example embodiments, the active side bottom surface BTA may be arranged at a higher vertical level than or above the dummy side bottom surface BTD. For example, the active side bottom surface BTA may be arranged at a first vertical level LV1, and the dummy side bottom surface BTD may be arranged at a vertical level lower than or below the first vertical level LV1.

For example, the active side bottom surface BTA may include an upper surface of the active side saddle portion SDA formed in the portion vertically overlapping the gate electrode 124, of the plurality of active areas ACT. For example, the dummy side bottom surface BTD may include an upper surface of the dummy side saddle portion SDD formed in the portion vertically overlapping the gate electrode 124, of the plurality of dummy active areas DACT. For example, in the inventive concept, the vertical level of the active side bottom surface BTA may be referred to as the vertical level of the uppermost surface of the active side saddle portion SDA, and the vertical level of the dummy side bottom surface BTD may be referred to as the vertical level of the uppermost surface of the dummy side saddle portion SDD. In addition, the vertical level of the upper surface of any component described below may mean the vertical level of the uppermost surface of the component.

According to some example embodiments, a first dummy active area DACT1 selected from the plurality of dummy active areas DACT may be arranged adjacent to the plurality of active areas ACT, and a second dummy active area DACT2 selected from the plurality of dummy active areas DACT may be horizontally apart from the plurality of active areas ACT with the first dummy active area DACT1 therebetween in the first horizontal direction (X direction). According to some example embodiments, the dummy side bottom surface BTD of the word line trench 120T may include a first dummy side bottom surface BTD1 exposing the first dummy active area DCAT1 and a second dummy side bottom surface BTD2 exposing the second dummy active area DCAT2. For example, the dummy side saddle portion SDD may include a first dummy side saddle portion SDD1 of the first dummy active area DACT1 and a second dummy side saddle portion SDD2 of the second dummy active area DACT2. For example, the first dummy side bottom surface BTD1 may correspond to an upper surface of the first dummy side saddle portion SDD1 and the second dummy side bottom surface BTD2 may correspond to an upper surface of the second dummy side saddle portion SDD2. According to various example embodiments, there may be more than two dummy active areas DACT between the plurality of active areas ACT and the boundary structure 114.

According to various example embodiments, the first dummy side bottom surface BTD1 may be arranged at a vertical level higher than or above the second dummy side bottom surface BTD2. For example, the first dummy side bottom surface BTD1 may be arranged at a second vertical level LV2 that is lower than or below the first vertical level LV1, and the second dummy side bottom surface BTD2 may be arranged at a third vertical level LV3 that is lower than the second vertical level LV2.

In FIGS. 2A through 2C and 2E, the outermost active areas ACT among the plurality of active areas ACT in the cell array area MCA which are most adjacent to the boundary area BA is illustrated as being apart from the boundary structure 114 with two dummy active areas DACT (for example, DCAT1 and DCAT2) therebetween but is not limited thereto. For example, in the first horizontal direction (X direction), one or, three or more dummy active areas DACT may be arranged between the outermost active area ACT and the boundary structure 114. For example, a first group of dummy active areas DACT including three or more dummy active areas DACT which are selected from among the plurality of the dummy active areas DACT may be arranged along the first horizontal direction (X direction) between the outermost active areas ACT and the boundary structure 114. In this case, the dummy side bottom surface BTD of the word line trench 120T exposing the first group of dummy active areas DCAT may have a lower vertical level as a portion of the dummy side bottom surface BTD that exposes the dummy active area DCAT arranged relatively far from the cell array area MCA.

As illustrated in FIGS. 2B, 2C, and 2E, each of the plurality of gate electrodes 124 may include a center portion 124a in the cell array area MCA and an edge portion 124b in the boundary area BA. According to some example embodiments, the center portion 124a may cross the plurality of active areas ACT and may extend long in the first horizontal direction (X direction). According to some example embodiments, the edge portion 124b may extend from the center portion 124a in the first horizontal direction (X direction) and may partially extend into the boundary structure 114 across the plurality of dummy active areas DACT. For example, the center portion 124a may vertically overlap the plurality of active areas ACT in the cell array area MCA, and the edge portion 124b may vertically overlap the plurality of dummy active areas DACT and a portion of the boundary structure 114 in the boundary area BA. For example, the edge portion 124b may be arranged on the dummy active area DACT.

When there is not enough space to arrange the gate electrode 124 on the dummy side saddle portion SDD, the gate electrode 124 cannot be or is difficult to be arranged on the plurality of dummy active areas DACT or only a small part of the gate electrode 124 may be arranged. In this case, there may be an issue that the electrical connection of the buried gate structure 120 relies on the conductive layer 126 or the electrical connection is cut off, resulting in increased resulting in increased resistance and/or electrical connection failure, compromising the yield and/or reliability of an integrated circuit device.

The gate electrode 124 of the integrated circuit device 100 according to some example embodiments of inventive concepts may continuously or contiguously extend in the first horizontal direction (X direction), e.g., without disconnection. For example, the gate electrode 124 may not include a cut-off portion in an area where the edge portion 124b of the gate electrode 124 fully or at least partly vertically overlaps the plurality of dummy active areas DACT. For example, as the upper surface of the dummy side saddle portion SDD of the plurality of dummy active areas DACT has a vertical level that is lower than the upper surface of the active side saddle portion SDA of the plurality of active areas ACT, a space for arranging the gate electrode 124 on the dummy side saddle portion SDD may be secured. Accordingly, the gate electrode 124 may continuously extend not only in the cell array area MCA but in the boundary area BA, e.g., without disconnection.

In some example embodiments, the vertical levels of the upper surface of the center portion 124a may be substantially the same as the upper surface of the edge portion 124b. For example, an upper surface 124u of the gate electrode 124 may have the same vertical level in the cell array area MCA and the boundary area BA. For example, the upper surface 124u of the gate electrode 124 may extend flat in the first horizontal direction (X direction).

Referring to FIGS. 2A and 2E, a portion of the center portion 124a that vertically overlaps the plurality of active areas ACT may have an active side width wa in the second horizontal direction (Y direction), and a portion of the edge portion 124b that vertically overlaps the plurality of dummy active areas DACT may have a dummy side width wb in the second horizontal direction (Y direction). According to some example embodiments, the dummy side width wb of the edge portion 124b may be greater than the active side width wa of the center portion 124a.

In some example embodiments, a portion of the edge portion 124b that vertically overlaps the first dummy active area DACT1 may have a first dummy side width wb1 in the second horizontal direction (Y direction), and a portion of the edge portion 124b that vertically overlaps the second dummy active area DACT2 may have a second dummy side width wb2 in the second horizontal direction (Y direction). In some example embodiments, the second dummy side width wb2 of the edge portion 124b may be greater than the first dummy side width wb1 of the edge portion 124b.

For example, unlike as illustrated in FIGS. 2A and 2E, a first group of dummy active areas DACT of the plurality of dummy active areas DACT that include three or more dummy active areas DACT may be arranged between the outermost active areas ACT of the plurality of active areas ACT arranged most adjacent to the boundary area BA and the boundary structure 114 in the first horizontal direction (X direction). In this case, a width in the second horizontal direction (Y direction) of a portion of the edge portion 124b that vertically overlaps the first group of dummy active areas DACT may be increase away from the cell array area MCA.

In FIGS. 2A and 2E, it is illustrated that in a plan view, the width of the center portion 124a in the second horizontal direction (Y direction) is constant, and a boundary thereof linearly extends in the first horizontal direction (X direction), but the embodiment is not limited thereto. For example, the width in the second horizontal direction (Y direction) of the center portion 124a that vertically overlaps the device isolation layer 112 may be greater than the active side width wa, so that in the plan view, the boundary of the center portion 124a may extend curvedly along the first horizontal direction (X direction). FIGS. 2A and 2E, illustrates that in a plan view, the width of the edge portion 124b in the second horizontal direction (Y direction) increases continuously, and the boundary of the edge portion 124b linearly expands, but the embodiment is not limited thereto. For example, a width in the second horizontal direction (Y direction) of a portion of the edge portion 124b, which vertically overlaps the device isolation layer 112, may be greater than the side width wb of edge portion 124b, In a plan view, the boundary of the edge portion 124b may have may extend/expand curvedly along the first horizontal direction (X direction) . . . . In this case also, the dummy side width wb of the edge portion 124b may be greater than the active side width wa of the center portion 124a, and the second dummy side width wb2 of the edge portion 124b may be greater than the first dummy side width wb1 of the edge portion 124b.

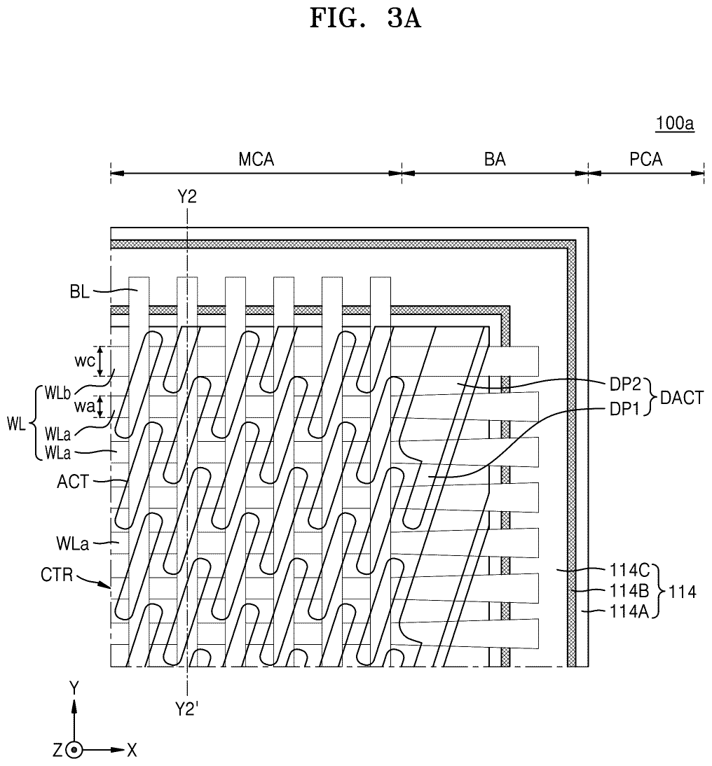

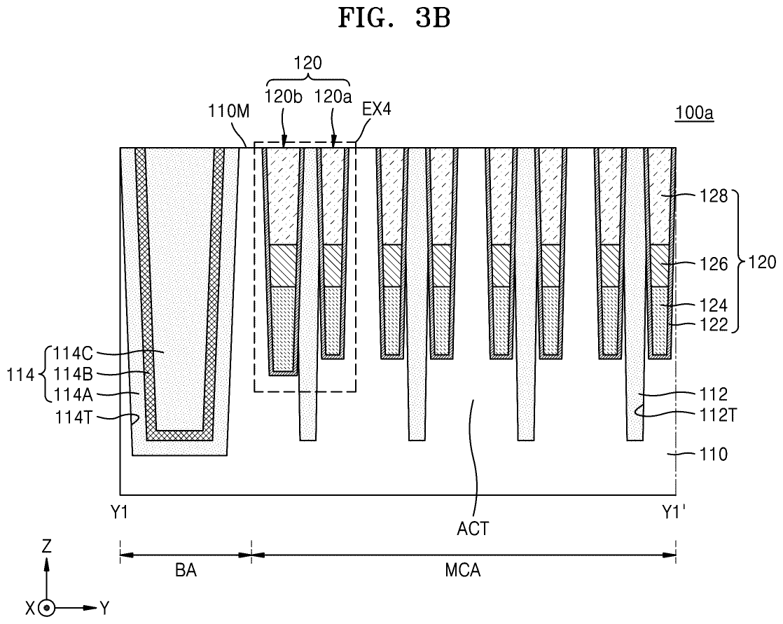

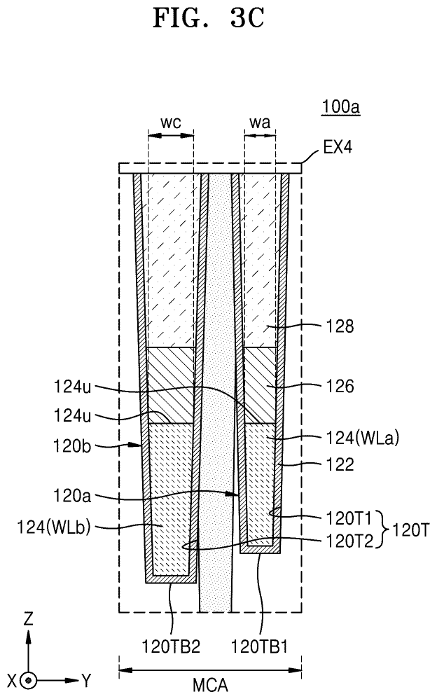

FIG. 3A is a layout diagram illustrating a schematic configuration of a portion of an integrated circuit device 100a according to some example embodiments, corresponding to FIG. 2A. FIG. 3B is a cross-sectional view taken along line Y2-Y2′ in FIG. 3A. FIG. 3C is an enlarged cross-sectional view of a region EX4 in FIG. 3B. In FIGS. 3A through 3C, the same reference numerals as those in FIGS. 2A through 2E may denote the same members, and descriptions thereof are omitted hereinafter. However, although the members are the same, the difference in structure and arrangement thereof is described.

Referring to FIG. 3A, the plurality of word lines WL may respectively include a plurality of first word lines WLa and a plurality of second word lines WLb. The plurality of second word lines WLb surround the plurality of first word lines WLa at both sides in the second horizontal direction (Y direction) of the plurality of first word lines WLa. In some example embodiments, the plurality of first word lines WLa may extend in the first horizontal direction (X direction) through the center portion of the cell array area MCA, and the plurality of second word lines WLb may surround the plurality of first word lines WLa at the edge portion of the cell array area MCA.

In some example embodiments, the plurality of first word lines WLa may be arranged along the second horizontal direction (Y direction) to form a first word line WLa array. According to various example embodiments, the plurality of second word lines WLb may be arranged on one side of the first word line WLa array and on the other side opposite to the one side in the second horizontal direction (Y direction). According to some example embodiments, the plurality of second word lines WLb may be arranged between the boundary structure 114 and the first word line WLa array, in the second horizontal direction (Y direction).

In FIG. 3A, it is illustrated that one second word line WLb is arranged between the first word line WLa array and the boundary structure 114, but the embodiment is not limited thereto. For example, two or more second word lines WLb may be arranged between the first word line WLa array and the boundary structure 114.

Referring to FIGS. 3A through 3C together, the substrate 110 of the integrated circuit device 100a may include the plurality of word line trenches 120T extending in the first horizontal direction (X direction) in parallel with each other, and the plurality of word line trenches 120T may include or define a plurality of first word line trenches 120T1 and a plurality of second word line trenches 120T2. In some example embodiments, the plurality of first word line trenches 120T1 may be arranged along the second horizontal direction (Y direction) in the center portion of the cell array area MCA, and the plurality of second word line trenches 120T2 may be arranged on both sides in the second horizontal direction (Y direction) of the plurality of first word line trenches 120T1 in the edge portion of the cell array area MCA.

For example, the plurality of first word line trenches 120T1 may extend in the first horizontal direction (X direction) through the center portion of the cell array area MCA, and the plurality of second word line trenches 120T2 may extend in the first horizontal direction (X direction) along the edge portion of the cell array area MCA.

According to some example embodiments, a width of each of the plurality of second word line trenches 120T2 in the second horizontal direction (Y direction) may be greater than a width of each of the plurality of first word line trenches 120T1 in the second horizontal direction (Y direction). According to some example embodiments, a bottom surface 120TB2 of the plurality of second word line trenches 120T2 may be arranged at a vertical level lower than a bottom surface 120TB1 of the plurality of first word line trenches 120T1.

According to some example embodiments, a plurality of buried gate structures may include a plurality of first buried gate structures 120a and a plurality of second buried gate structures 120b. According to some example embodiments, the plurality of first buried gate structures 120a may be individually and respectively arranged in the plurality of first word line trenches 120T1, and the plurality of second buried gate structures 120b may be individually and respectively arranged in the plurality of second word line trenches 120T2.

According to some example embodiments, each of the plurality of first buried gate structures 120a and each of the plurality of second buried gate structures 120b may include the gate dielectric layer 122, the gate electrode 124, the conductive layer 126, and the capping insulating layer 128. For example, the gate electrodes 124 of the plurality of first buried gate structures 120a may respectively correspond to the plurality of first word lines WLa illustrated in FIG. 3A, and the gate electrodes 124 of the plurality of second buried gate structures 120b may respectively correspond to the plurality of second word lines WLb illustrated in FIG. 3A.

The plurality of first buried gate structures 120a may have substantially the same structure as the plurality of buried gate structures 120 of the integrated circuit device 100 illustrated in FIGS. 2A through 2E. For example, the gate electrode 124 of each of the plurality of first buried gate structures 120a (for example, the plurality of first word lines WLa) may include the center portion 124a and the edge portion 124b.

According to some example embodiments, the plurality of second word lines WLb may have a uniform width in the second horizontal direction (Y direction) and extend along the first horizontal direction (X direction) in the cell array area MCA and the boundary area BA. For example, a portion of the plurality of second word lines WLb that vertically overlaps the plurality of active areas ACT may have a first expanded width wc in the second horizontal direction (Y direction).

A portion of the plurality of second word lines WLb that vertically overlaps the plurality of dummy active areas DACT may have the same width in the second horizontal direction (Y direction) as the first expanded width wc.

In some example embodiments, the first expanded width wc of the plurality of second word lines WLb may be greater than the active side width wa of the center portion of the plurality of first word lines WLa (for example, the width in the second horizontal direction (Y direction) of a portion vertically overlapping the plurality of active areas ACT of the plurality of first word lines WLa).

FIG. 3A illustrates that in a plan view, the second word line WLb extends linearly in the first horizontal direction (X direction) having constant width thereof, but the embodiment is not limited thereto. For example, the width in the second horizontal direction (Y direction) of the second word line (WLb) fully or at least partly vertically overlapping the device isolation layer 112 may be greater than the first expanded width wc of the plurality of second word lines WLb, and in the plan view, the boundary of the second word line WLb may extend curvedly in the first horizontal direction (X direction). Even in this case, the first expanded width wc of the second word line WLb may be greater than the active side width wa of the center portion of the plurality of first word lines WLa.

In some example embodiments, the bottom surface of the plurality of second word lines WLb may be arranged at a vertical level lower than the bottom surface of the plurality of first word lines WLa. In some example embodiments, the upper surface 124u of the plurality of second word lines WLb may be arranged at the same vertical level as the upper surface 124u of the plurality of first word lines WLa.

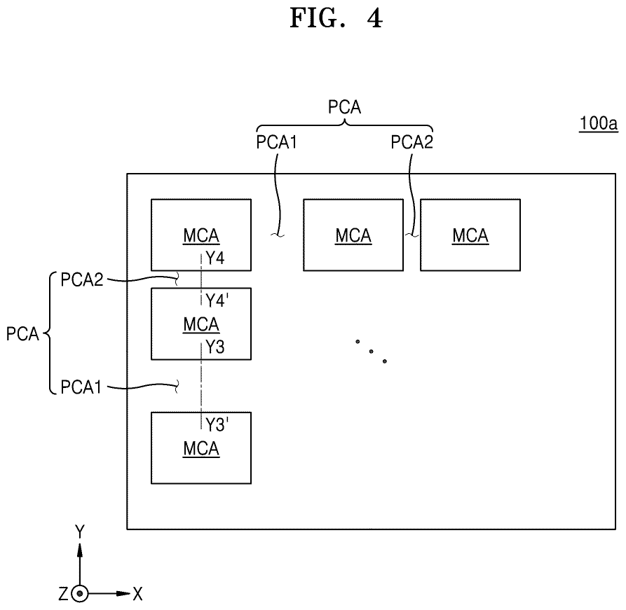

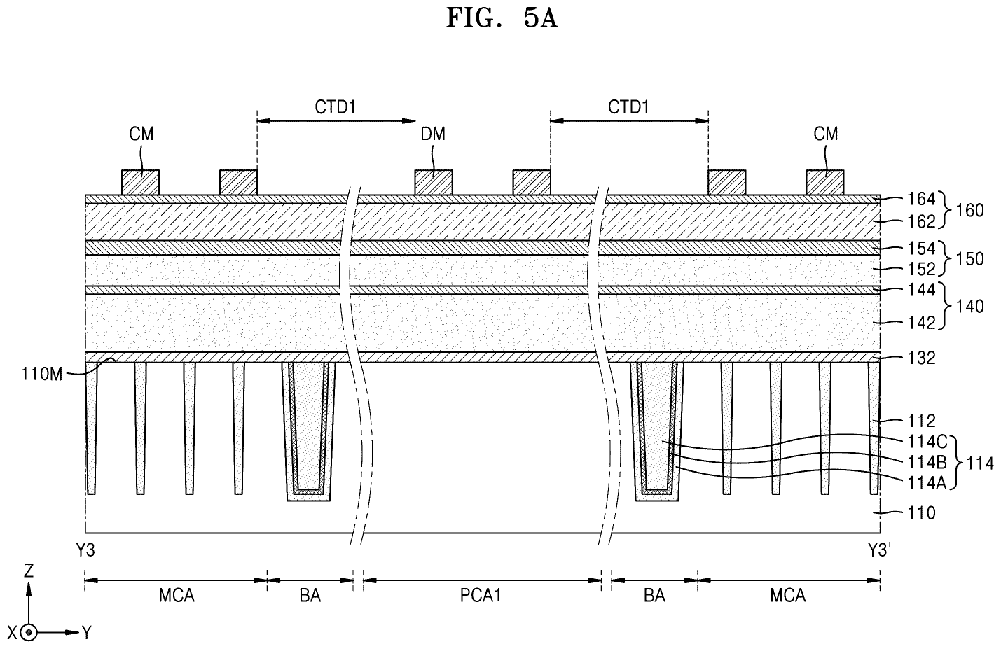

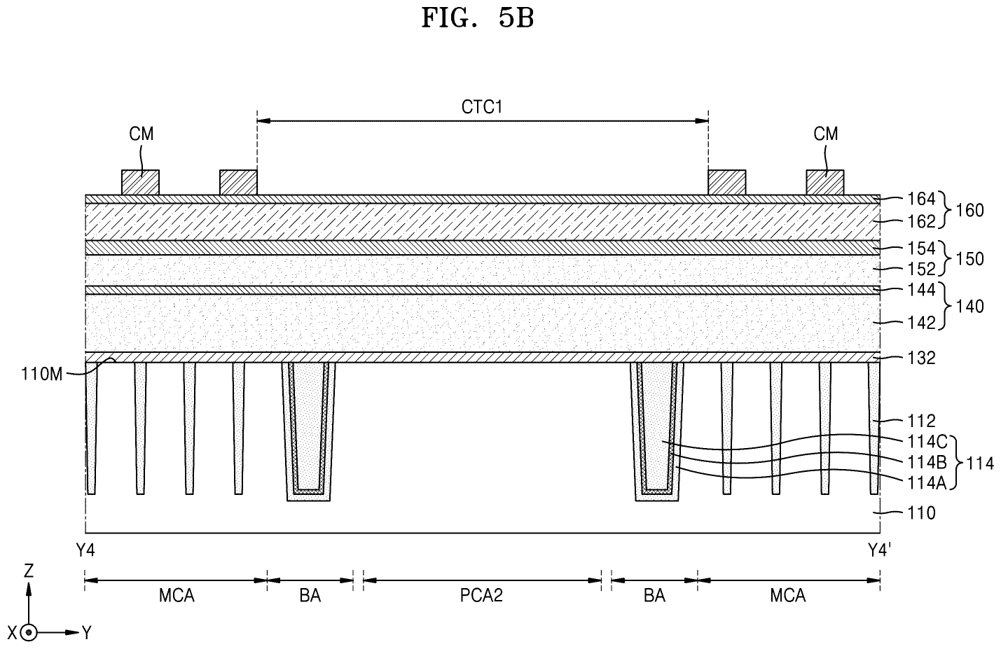

FIG. 4 is a layout diagram illustrating a schematic configuration of the integrated circuit device 100a according to various example embodiments. FIG. 5A is a cross-sectional view taken along line Y3-Y3′ in FIG. 4, with respect to which a method of manufacturing the integrated circuit device 100a, according to various example embodiments is described. FIG. 5B is a cross-sectional view taken along line Y4-Y4′ in FIG. 4, with respect to which for illustrating a method of manufacturing the integrated circuit device 100a, according to some example embodiments, is described. FIG. 5A illustrates a cross-section of the first periphery circuit area PCA1 of the periphery circuit area PCA, and FIG. 5B illustrates a cross-section of the second periphery circuit area PCA2 of the periphery circuit area PCA.

Referring to FIGS. 5A and 5B, the plurality of active areas ACT and the plurality of dummy active areas DACT (refer to FIGS. 2A through 2E) may also prepare the defined substrate 110 by using the device isolation layer 112. The substrate 110 may include the boundary structure 114 surrounding the plurality of active areas ACT and the plurality of dummy active areas DACT.

According to some example embodiments, a lower protection layer 132, a first sacrificial layer 140, a second sacrificial layer 150, and a third sacrificial layer 160 may be sequentially formed on the substrate 110 (first operation). According to various example embodiments, each of the lower protection layer 132, the first sacrificial layer 140, the second sacrificial layer 150, and the third sacrificial layer 160 may be formed, e.g., with an atomic layer deposition (ALD) process and/or with a chemical vapor deposition (CVD) process.

According to some example embodiments, the lower protection layer 132 may include at least one of silicon oxide, silicon nitride, and silicon oxynitride. In some example embodiments, the lower protection layer 132 may include a single layer including silicon oxide. In some example embodiments, the lower protection layer 132 may include or be a multilayer. For example, the lower protection layer 132 may include a multilayer including two or more layers, and each layer constituting the multilayer may include any one of silicon oxide, silicon nitride, and silicon oxynitride. According to some example embodiments, the lower protection layer 132 may be formed on the substrate 110 by using one or more of an atomic layer deposition (ALD) process, a chemical vapor deposition (CVD) process, a plasma-enhanced CVD (PECVD) process, a low pressure CVD (LPCVD) process, etc.

According to some example embodiments, the first sacrificial layer 140 may include a first lower sacrificial layer 142 and a first upper sacrificial layer 144. For example, the first lower sacrificial layer 142 and the first upper sacrificial layer 144 may be sequentially formed on the lower protection layer 132. According to some example embodiments, the first lower sacrificial layer 142 and the first upper sacrificial layer 144 may have different etching selectivities from each other. According to some example embodiments, the first lower sacrificial layer 142 may include an amorphous carbon layer (ACL) and/or a spin-on hardmask. For example, the spin-on hard mask may include a carbon-based spin-on hardmask (C-SOH). In some example embodiments, the first lower sacrificial layer 142 may be formed by depositing ACLs on the lower protection layer 132 by using one or more of an ALD process, a CVD process, a PECVD process, an LPCVD process, etc. In some example embodiments, the first lower sacrificial layer 142 may be formed as a single ACL. In some other embodiments, the first lower sacrificial layer 142 may also include a carbon-based multilayer. According to some example embodiments, the first upper sacrificial layer 144 may include a single layer including silicon nitride or silicon oxynitride. For example, the first upper sacrificial layer 144 may be formed on the first lower sacrificial layer 142 by using one or more of an ALD process, a CVD process, a PECVD process, an LPCVD process, etc.

According to some example embodiments, the second sacrificial layer 150 may include a second lower sacrificial layer 152 and a second upper sacrificial layer 154. For example, the second lower sacrificial layer 152 and the second upper sacrificial layer 154 may be sequentially formed on the first sacrificial layer 140. According to some example embodiments, the second lower sacrificial layer 152 and the second upper sacrificial layer 154 may have different etching selectivity from each other. According to some example embodiments, the second lower sacrificial layer 152 may include an ACL or a spin-on hard mask. In some example embodiments, the second lower sacrificial layer 152 may be formed by depositing the ACL on the first upper sacrificial layer 144 by using one or more of an ALD process, a CVD process, a PECVD process, an LPCVD process, etc. In some example embodiments, the second lower sacrificial layer 152 may be formed as a single layer including the ACL. In some other embodiments, the second lower sacrificial layer 152 may also include a carbon-based multilayer. According to some example embodiments, the second upper sacrificial layer 154 may include a single layer including silicon nitride or silicon oxynitride. For example, the second upper sacrificial layer 154 may be formed on the second lower sacrificial layer 152 by using one or more of an ALD process, a CVD process, a PECVD process, an LPCVD process, etc.

According to some example embodiments, the third sacrificial layer 160 may include a third lower sacrificial layer 162 and a third upper sacrificial layer 164. For example, the third lower sacrificial layer 162 and the third upper sacrificial layer 164 may be sequentially formed on the second sacrificial layer 150. According to some example embodiments, the third lower sacrificial layer 162 and the third upper sacrificial layer 164 may have different etching selectivity from each other. For example, each of the third lower sacrificial layer 162 and the third upper sacrificial layer 164 may include any one or more than one of silicon oxide, silicon nitride, silicon oxynitride, and a spin-on hard mask. For example, the third lower sacrificial layer 162 may include a single layer including a spin-on hard mask, and the third upper sacrificial layer 164 may include a single layer including silicon nitride or silicon oxide. According to some example embodiments, the third upper sacrificial layer 164 may be formed on the third lower sacrificial layer 162 by using one or more of an ALD process, a CVD process, a PECVD process, an LPCVD process, etc.

Referring to FIGS. 5A and 5B, a cell mask pattern CM may be arranged on the third sacrificial layer 160 in the cell array area MCA. According to some example embodiments, the cell mask pattern CM may be formed by doping, e.g., implanting, a photoresist material on the third upper sacrificial layer 164, and then by performing exposure and development processes. For example, the cell mask pattern CM may, in a plan view, cross the cell array area MCA and extend long in the first horizontal direction (X direction) and may partially extend into the boundary area BA.

Referring to FIG. 5A, in the first periphery circuit area PCA1, a dummy mask pattern DM may be formed on the third sacrificial layer 160. For example, the dummy mask pattern DM may be formed together with the cell mask pattern CM in the same process as the cell mask pattern CM. For example, the dummy mask pattern DM may extend in the first periphery circuit area PCA1 in the first horizontal direction (X direction).

According to various example embodiments, the dummy mask pattern DM may be apart from the cell mask pattern CM in the horizontal direction (X direction and/or Y direction). According to some example embodiments, in the first periphery circuit area PCA1, the dummy mask pattern DM may be apart from the cell mask pattern CM by a first separation distance CTD1 in the horizontal direction (X direction and/or Y direction). For example, the dummy mask pattern DM of the first periphery circuit area PCA1 may be apart from the cell mask pattern CM of the cell array area MCA on one side of the first periphery circuit area PCA1 by the first separation distance CTD1 and may be apart from the cell mask pattern CM of the cell array area MCA on the other side of the first periphery circuit area PCA1 by the first separation distance CTD1.

In FIGS. 5A and 5B, it is illustrated that in two adjacent cell array areas MCA in the second horizontal direction (Y direction) and the first periphery circuit area PCA1 therebetween, the dummy mask pattern DM and the cell mask pattern CM are apart from each other in the second horizontal direction (Y direction), but embodiments are not limited thereto. For example, in two adjacent cell array areas MCA in the first horizontal direction (X direction) and the first periphery circuit area PCA1 therebetween (refer to FIG. 4), the dummy mask pattern DM and the cell mask pattern CM may be apart from each other in the first horizontal direction (X direction). In this case, the dummy mask pattern DM and the cell mask pattern CM may be apart from each other by the first separation distance CTD1.

Referring to FIGS. 5B and 5C, unlike in the first periphery circuit area PCA1, in the second periphery circuit area PCA2, the dummy mask pattern DM may not be arranged on the third sacrificial layer 160. For example, when a horizontal distance between two relatively adjacent cell array areas MCA is small, the dummy mask pattern DM may not be arranged.

According to some example embodiments, a first cell mask pattern CM and a second cell mask pattern CM may be arranged in each of two cell array areas MCA apart from each other with the second periphery circuit area PCA2 therebetween. According to some example embodiments, the first cell mask pattern CM may be apart from the second cell mask pattern CM by a second separation distance CTC1 in the horizontal direction (X direction and/or Y direction). In FIG. 5B, it is illustrated that the first cell mask pattern CM and the second cell mask pattern CM are apart from each other in the second horizontal direction (Y direction) with the second periphery circuit area PCA2 therebetween, but the embodiment is not limited thereto. For example, in the first horizontal direction (X direction), two cell array areas MCA may be arranged adjacent to each other with the second periphery circuit area PCA2 therebetween (refer to FIG. 4), and in this case, each of the cell mask patterns CM on each cell array area MCA may be apart from each other by the second separation distance CTC1 in the first horizontal direction (X direction).

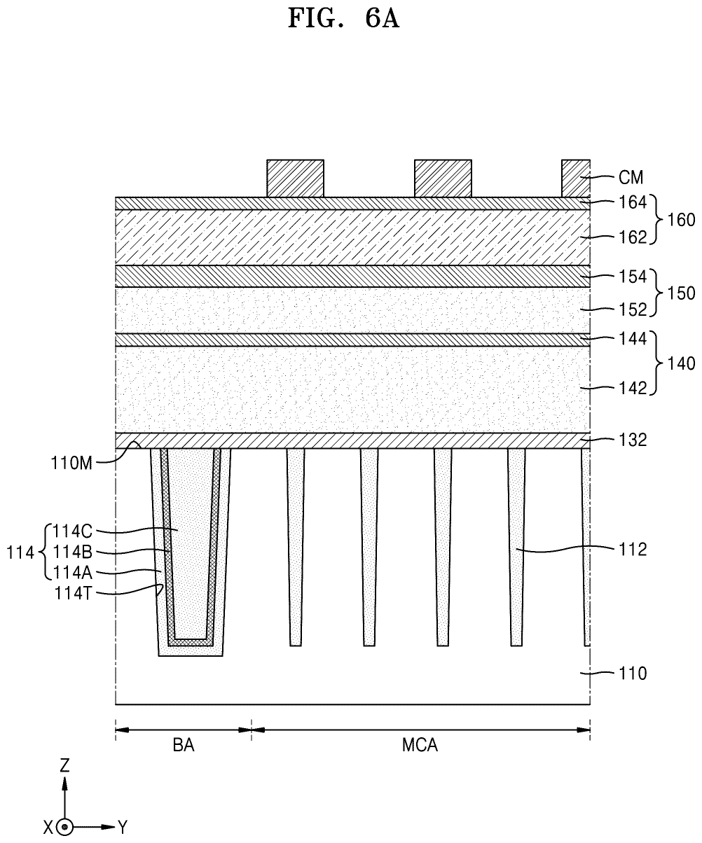

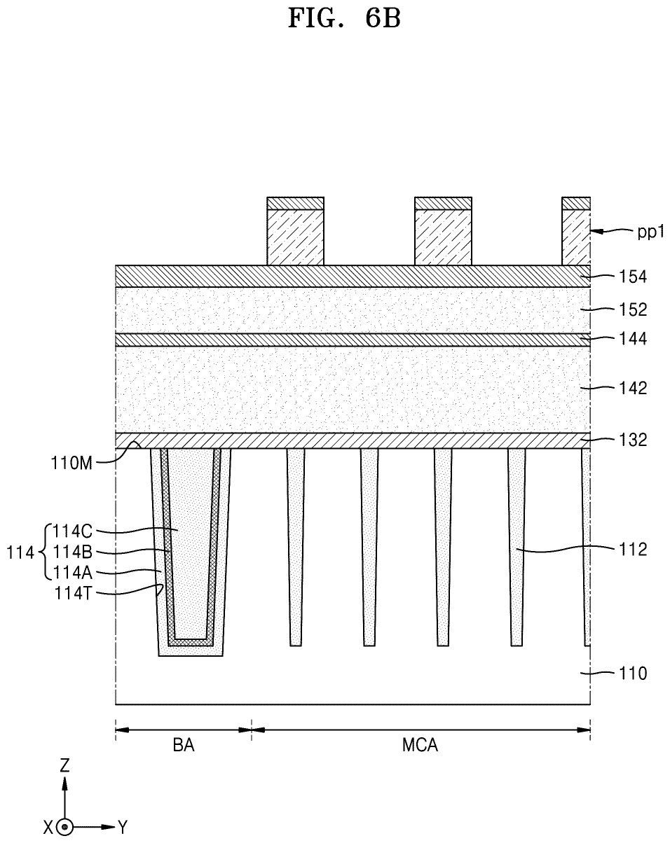

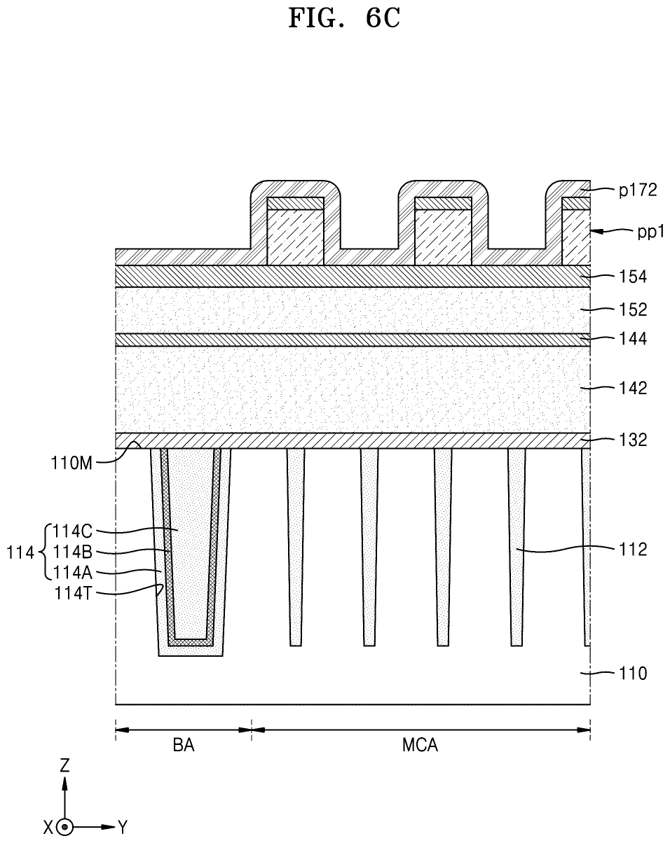

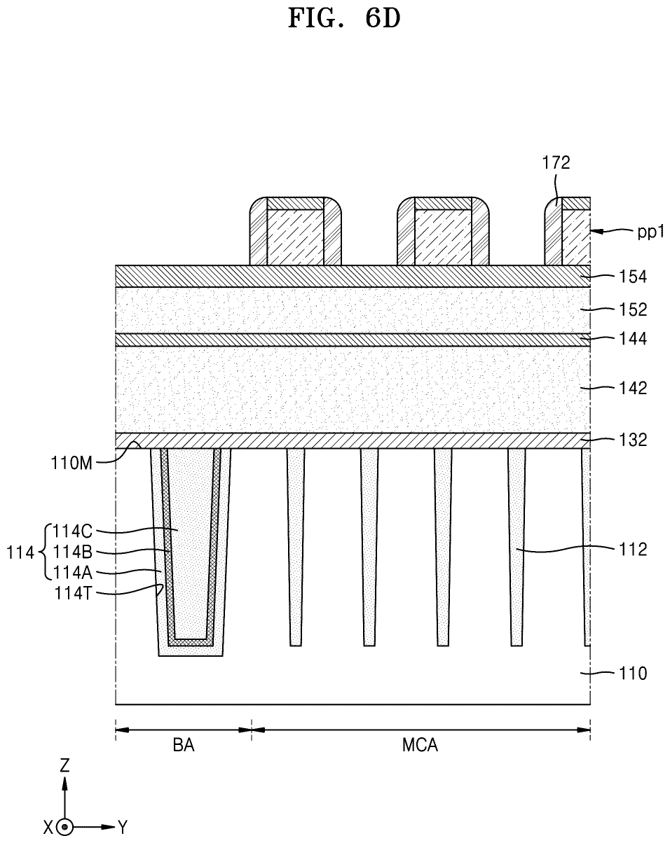

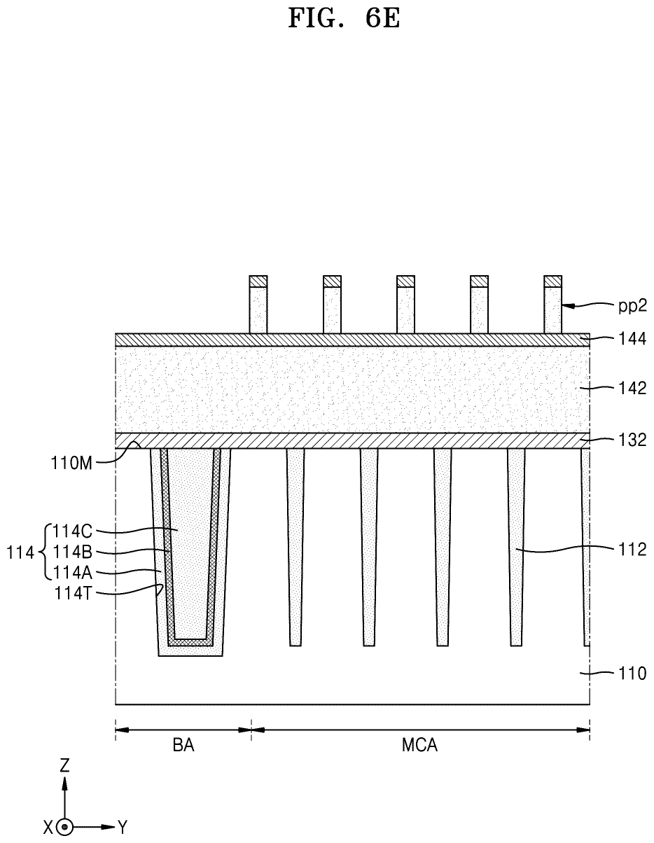

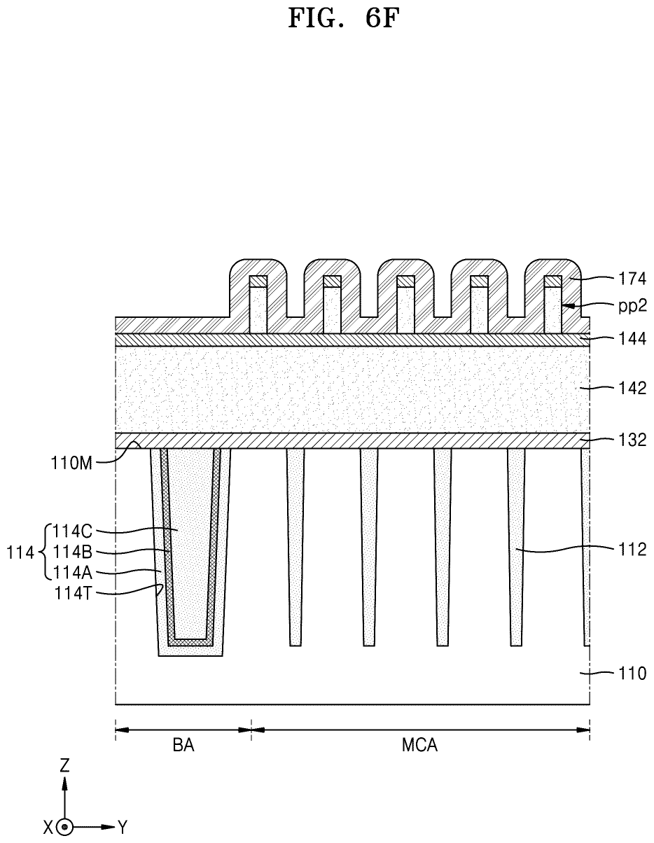

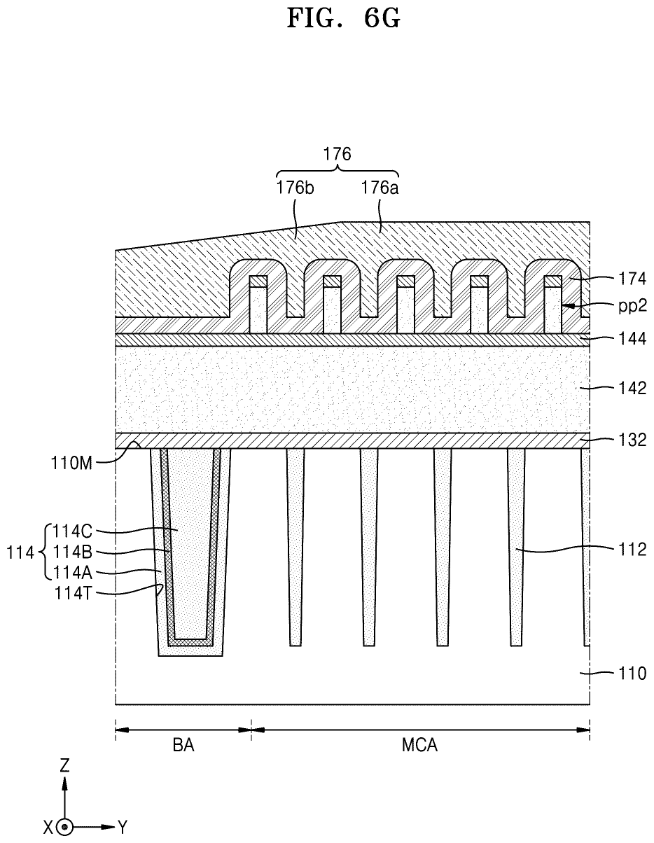

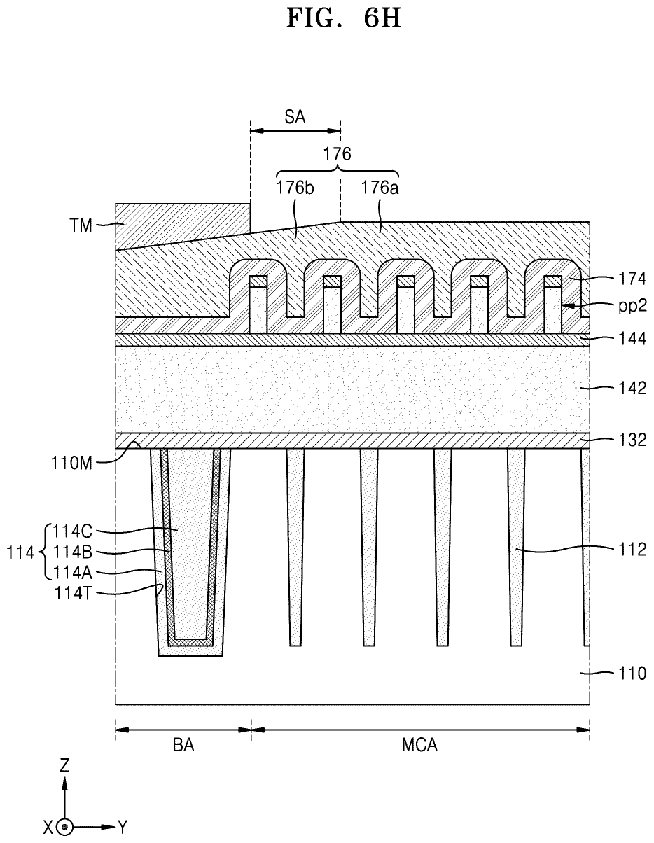

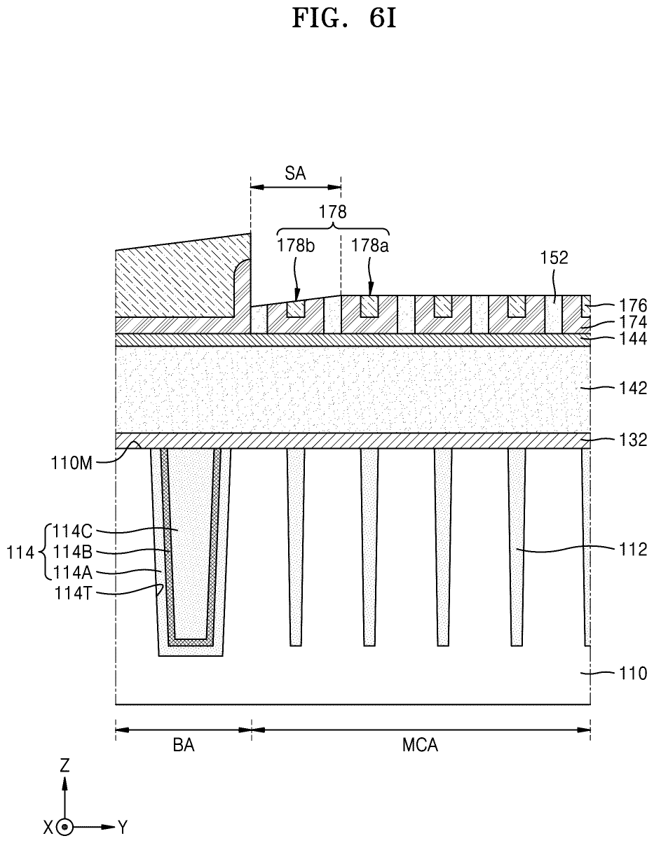

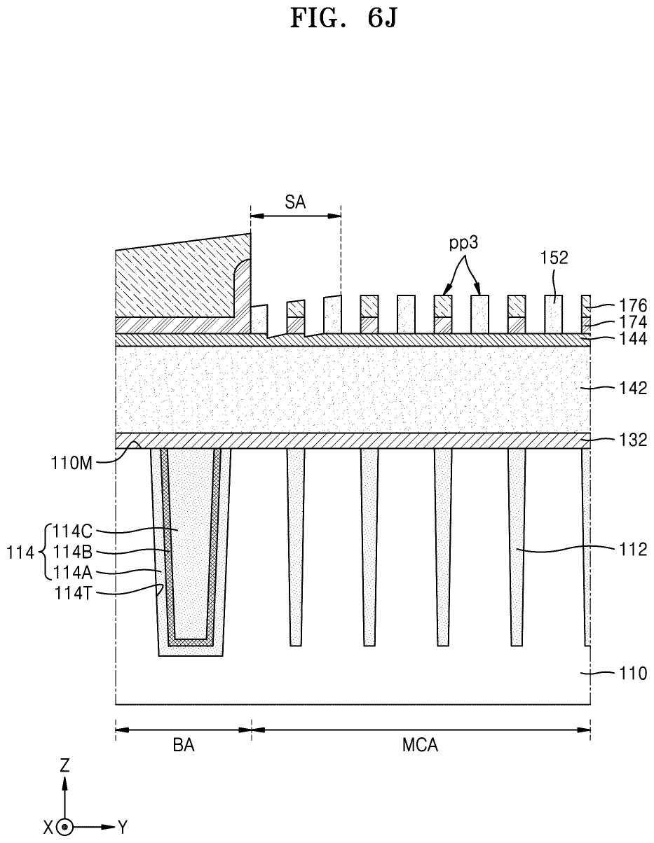

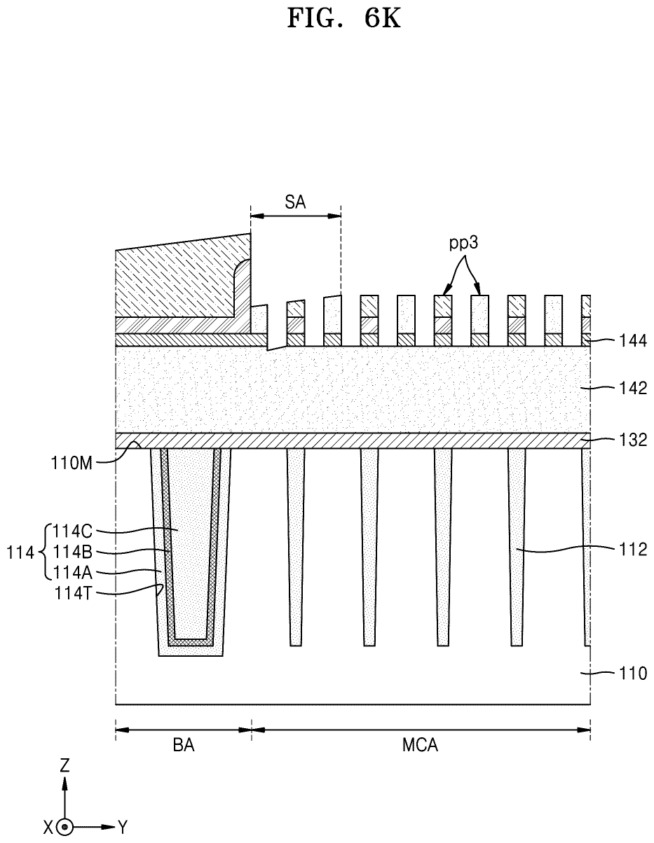

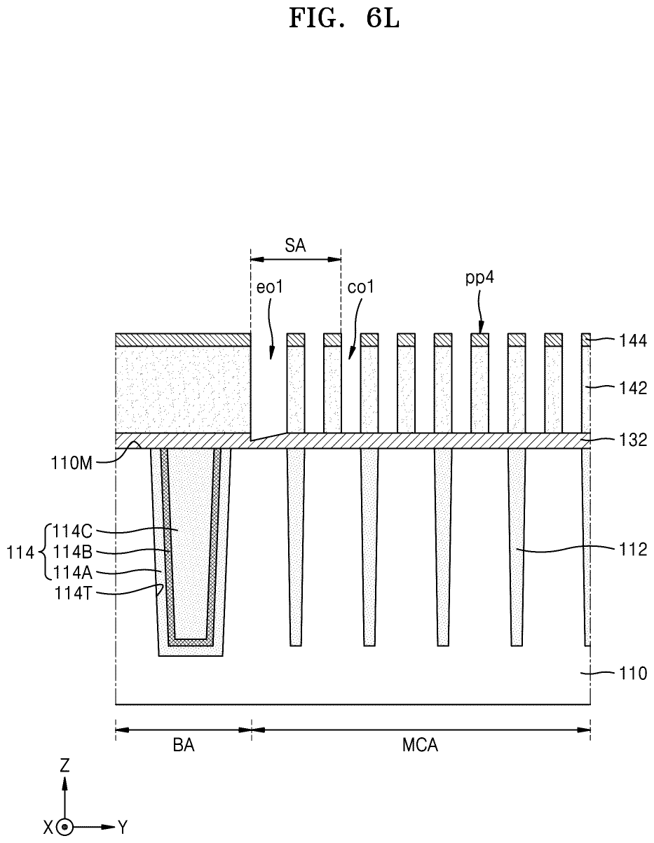

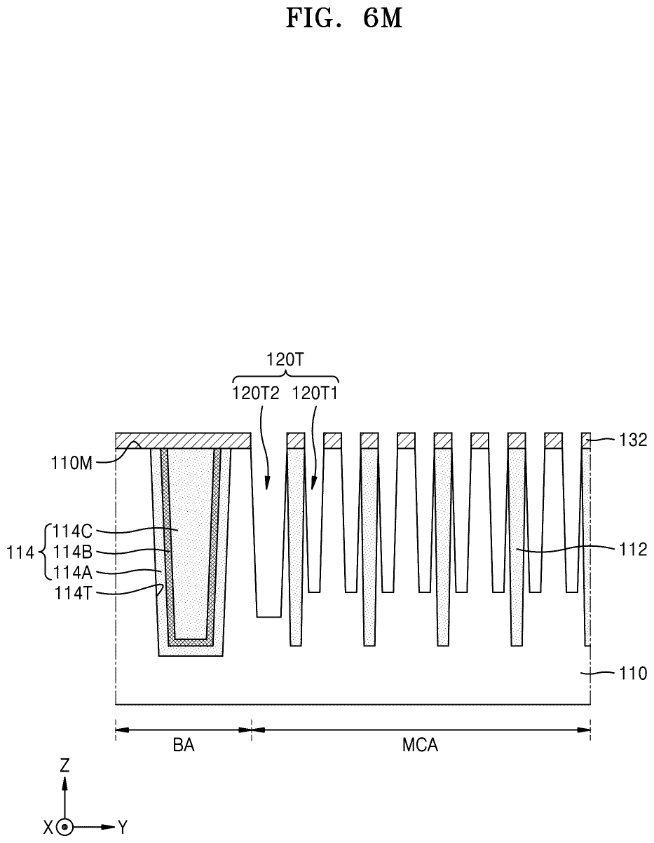

According to some example embodiments, the first separation distance CTD1 may be the same as the second separation distance CTC1. In some example embodiments, two cell mask patterns CM (for example, the first cell mask pattern CM and the second cell mask pattern CM) arranged in two adjacent cell array areas MCA may be apart from each other by the second separation distance CTC1. For example, when the distance between the first cell mask pattern CM and the second cell mask pattern CM exceeds the second separation distance CTC1, the dummy mask pattern DM may be arranged between the first cell mask pattern CM and the second cell mask pattern CM (refer to FIG. 5A). In this case, each of the distance between the dummy mask pattern DM and the first cell mask pattern CM and the distance between the dummy mask pattern DM and the second cell mask pattern CM may be the first separation distance CTD1, and the first separation distance CTD1 may be the same as the second separation distance CTC1. Accordingly, in the method of manufacturing the integrated circuit device 100a to be described below with reference to FIGS. 6A through 6M, a third mask layer 176 (refer to FIG. 6G) having a downward slope from the boundary of the cell array area MCA to the periphery circuit area PCA may be formed.

FIGS. 6A through 6M are cross-sectional views illustrating cross-sections of the cell array area MCA and the boundary area BA according to the process sequence of a method of manufacturing an integrated circuit device, according to various example embodiments. FIGS. 6A through 6M are cross-sectional views illustrating portions of the cell array area MCA and the boundary area BA in FIGS. 5A and 5B according to the process sequence.

Referring to FIGS. 6A and 6B, a first sacrificial pattern pp1 may be formed by removing a portion of the third sacrificial layer 160 by using the cell mask pattern CM as an etching mask. For example, a portion of the third sacrificial layer 160 may be removed by using a dry etching process. In some example embodiments, the first sacrificial pattern pp1 may include the third lower sacrificial layer 162 and the third upper sacrificial layer 164, which are remainders after removal. In some example embodiments, an upper surface of the second upper sacrificial layer 154 may be partially exposed through a first pattern opening defined by the first sacrificial pattern pp1. For example, the second upper sacrificial layer 154 may be used as an etching stop layer in an etching process for forming the first sacrificial pattern pp1.

Referring to FIGS. 6B and 6C, a first mask layer p172 conformally covering the first sacrificial pattern pp1 and the exposed second upper sacrificial layer 154 may be formed on the resultant product of FIG. 6B. According to some example embodiments, the first mask layer p172 may conformally cover the upper surface of the first sacrificial pattern pp1 and first and second, or both sidewalls and the upper surface of the exposed second upper sacrificial layer 154. According to some example embodiments, the first mask layer p172 may include silicon oxide. According to some example embodiments, the first mask layer p172 may be formed by using an ALD process. For example, the first mask layer p172, the third upper sacrificial layer 164 (refer to FIG. 6A), and the second upper sacrificial layer 154 may have the same etching selectivity.

Referring to FIGS. 6B and 6D, a portion of the first mask layer p172 may be removed to form a first mask pattern 172 and accordingly, portions of the upper surface of the first sacrificial pattern pp1 and the second upper sacrificial layer 154 may be exposed. For example, the operation of forming the first mask pattern 172 may be performed by using a dry etching process.

Referring to FIGS. 6D and 6E, a second sacrificial pattern pp2 may be formed by removing portions of the first sacrificial pattern pp1 and the second sacrificial layer 150 by using the first mask pattern 172 as an etching mask. For example, the operation of forming the second sacrificial pattern pp2 may be performed by using an anisotropic etching process, such as a dry etching process. In some example embodiments, in the operation of forming the second sacrificial pattern pp2, the first mask pattern 172 may also be removed. For example, the second sacrificial pattern pp2 may include remainders of the second lower sacrificial layer 152 and the second upper sacrificial layer 154, which have been removed. In some example embodiments, the upper surface of the first upper sacrificial layer 144 may be partially exposed through a second pattern opening defined by the second sacrificial pattern pp2. For example, the first upper sacrificial layer 144 may be used as an etching stop film in an etching process for forming the first sacrificial pattern pp1.

Referring to FIGS. 6E and 6F, a second mask layer 174 conformally covering the second sacrificial pattern pp2 and the exposed first upper sacrificial layer 144 may be formed on the resultant product of FIG. 6E. According to some example embodiments, the second mask layer 174 may conformally cover the upper surface and both sidewalls of the second sacrificial pattern pp2, and the upper surface of the exposed first upper sacrificial layer 144. According to some example embodiments, the second mask layer 174 may include silicon oxide and may be formed by using an ALD process. For example, a portion covering the upper surface of the second sacrificial pattern pp2 of the second mask layer 174 may have a higher vertical level than a portion covering the upper surface of the first upper sacrificial layer 144.

For example, the second mask layer 174 may have an uneven cross-section according to an interval of the second sacrificial pattern pp2 in the cell array area MCA.

Referring to FIGS. 6F and 6G, the third mask layer 176 covering the second mask layer 174 may be formed on the resultant product of FIG. 6F. According to some example embodiments, the third mask layer 176 may be formed by using a spin-on hard mask.

According to some example embodiments, the third mask layer 176 may include a flat portion 176a and an inclined portion 176b. According to some example embodiments, the flat portion 176a may be arranged at the center portion of the cell array area MCA, and the inclined portion 176b may extend to the boundary area BA (or the periphery circuit area PCA) near the boundary of the cell array area MCA. For example, the vertical level of the upper surface of the inclined portion 176b may gradually decrease as the inclined portion 176b extends in the direction of the periphery circuit area PCA (or the boundary area BA). For example, the upper surface of the inclined portion 176b may have a downward slope in the direction of the periphery circuit area PCA (of the boundary area BA). In some example embodiments, the upper surface of the inclined portion 176b may have a lower vertical level than the upper surface of the flat portion 176a.

In some example embodiments, the inclined portion 176b may at least partially and vertically overlap the second sacrificial pattern pp2. For example, the inclined portion 176b may vertically overlap a portion of the second sacrificial pattern pp2 arranged near the edges of both sides in the second horizontal direction (Y direction) of the cell array area MCA.

In some example embodiments, although not illustrated, the second sacrificial pattern pp2 may cross the cell array area MCA and extend long in the first horizontal direction (X direction) and may partially extend into the boundary area BA at both sides thereof in the first horizontal direction (X direction). Accordingly, the inclined portion 176b may be formed on the dummy active area DACT (refer to FIGS. 2A through 2E). For example, the inclined portion 176b may vertically overlap the plurality of active areas ACT on both sides in the second horizontal direction (Y direction) of the cell array area MCA and may not vertically overlap the plurality of active areas ACT on both sides in the first horizontal direction (X direction) of the cell array area MCA. In this case, the inclined portion 176b may vertically overlap the plurality of dummy active areas DACT of the boundary area BA, which are arranged near both sides in the first horizontal direction (X direction) of the cell array area MCA. For example, the inclined portion 176b may be formed near four surfaces of the cell array area MCA.

In some example embodiments, the inclined portion 176b may not be arranged in the cell array area MCA but may be arranged only in the boundary area BA. For example, the inclined portion 176b may not vertically overlap the plurality of active areas ACT of the cell array area MCA and may vertically overlap only the dummy active area DACT (refer to FIGS. 2A through 2E) of the boundary area BA. For example, the inclined portion 176b may be formed near both sides of the cell array area MCA in the first horizontal direction (X direction), and the integrated circuit device 100 described with reference to FIGS. 2A through 2E may be manufactured by performing the manufacturing process described below.

Referring to FIGS. 6G and 6H together, an opening mask TM covering a portion of the inclined portion 176b may be formed on the inclined portion 176b. According to some example embodiments, portions of the flat portion 176a and the inclined portion 176b may be exposed by the opening mask TM. For example, an inclined area SA, which is an area in which a portion of the inclined portion 176b exposed by the opening mask TM is arranged, may be defined. According to some example embodiments, the opening mask TM may include a photoresist pattern formed by performing exposure and development processes after applying a photoresist material on the third mask layer 176.

Referring to FIGS. 6H and 6I, the opening mask TM may be used as an etching mask to form a residual pattern structure 178, by removing portions of the second sacrificial pattern pp2, the second mask layer 174, and the third mask layer 176. In some example embodiments, the residual pattern structure 178 may include the second lower sacrificial layer 152, the second mask layer 174, and the third mask layer 176, which remain after being removed during an etching process. For example, as the upper surface of the residual pattern structure 178, the upper surface of the second lower sacrificial layer 152, the upper surface of the second mask layer 174, and the upper surface of the third mask layer 176, which remain after removal, may be exposed. Thereafter, the opening mask TM may be removed.

In some example embodiments, the residual pattern structure 178 may be formed by using a dry etching process, in which the second sacrificial pattern pp2, the second mask layer 174, and the third mask layer 176 are etched without mutual selectivity. In some example embodiments, the residual pattern structure 178 may include a flat portion 178a and an inclined portion 178b, and the inclined portion 178b may be formed in the inclined area SA. For example, the profiles of the upper surface of the flat portion 178a and the upper surface of the inclined portion 178b of the residual pattern structure 178 may correspond to the profiles of the upper surface of the flat portion 176a and the upper surface of the inclined portion 176b of the third mask layer exposed by the opening mask TM, respectively.

Referring to FIGS. 6I and 6J, a third sacrificial pattern pp3 may be formed by removing a portion of the second mask layer 174 by using the second lower sacrificial layer 152 and the third mask layer 176, which constitute the residual pattern structure 178. For example, a portion of the second mask layer 174 may be removed by using a dry etching process.

In some example embodiments, the third sacrificial pattern pp3 may include the second lower sacrificial layer 152, the second mask layer 174, and the third mask layer 176, which remain after removal. In some example embodiments, the upper surface of the first upper sacrificial layer 144 may be partially exposed through a third pattern opening defined by the third sacrificial pattern pp3. For example, the first upper sacrificial layer 144 may be used as an etching stop layer, in an etching process for forming the third sacrificial pattern pp3.

In some example embodiments, the upper surface of the third sacrificial pattern pp3 may have a profile corresponding to the upper surface of the inclined portion 178b of the residual pattern structure 178 in the inclined area SA. For example, the upper surface of the third sacrificial pattern pp3 in the inclined area SA may have a downward slope, and may have a lower vertical level than the upper surface of a portion of the third sacrificial pattern pp3, which is not arranged in the inclined area SA, (for example, a portion of the third sacrificial pattern pp3 arranged in a flat area excluding the inclined area SA).

In some example embodiments, a portion of the first upper sacrificial layer 144 may be removed in the inclined area SA. For example, in the inclined area SA, the upper surface of the first upper sacrificial layer 144 may have a downward inclined profile. For example, the first upper sacrificial layer 144 may be used as an etching stop layer in the etching process for forming the third sacrificial pattern pp3, but despite the etching selectivity, a portion of the first upper sacrificial layer 144 may be removed in the inclined area SA due to the downward slope profile of the residual pattern structure 178 formed in the inclined area SA.

Referring to FIGS. 6J and 6K, a portion of the first upper sacrificial layer 144 may be removed by using the third sacrificial pattern pp3 as an etching mask. For example, a portion of the first upper sacrificial layer 144 may be removed by using a dry etching process. Accordingly, a portion of the upper surface of the first lower sacrificial layer 142 may be exposed.

According to some example embodiments, the upper surface of a portion of the exposed first lower sacrificial layer 142 arranged in the inclined area SA may be arranged at a lower vertical level than the upper surface of a portion arranged in another area (for example, the flat area). For example, in the process of removing a portion of the first upper sacrificial layer 144, a portion of the first lower sacrificial layer 142 of the inclined area SA may also be removed.

Referring to FIGS. 6K and 6L, a portion of the first upper sacrificial layer 144 may be removed by using the third sacrificial pattern pp3 as an etching mask to form a fourth sacrificial pattern pp4. In some example embodiments, in the process of forming the third sacrificial pattern pp3, the second lower sacrificial layer 152, the second mask layer 174, and the third mask layer 176, which have remained on the first upper sacrificial layer 144, may also be removed.

In some example embodiments, the fourth sacrificial pattern pp4 may include the first lower sacrificial layer 142 and the first upper sacrificial layer 144, which have remained after being removed in the etching process. In some example embodiments, the upper surface of the lower protection layer 132 may be partially exposed through a fourth pattern opening defined by the fourth sacrificial pattern pp4.

In some example embodiments, the fourth pattern opening may include an expansion opening col and a cell opening col. In some example embodiments, the expansion opening col may be formed in the inclined area SA. For example, although not illustrated, the expansion opening col may be formed in the dummy active area DCAT (refer to FIGS. 2A through 2E).

In some example embodiments, the upper surface of the third sacrificial pattern pp3 may have a lower vertical level in the inclined area SA than in the flat area, and in the process of forming the fourth sacrificial pattern pp4, the first lower sacrificial layer 142 may be over-etched in the inclined area SA to form the expansion opening col. For example, the expansion opening col may form a space more expanded than the cell opening col.

In FIG. 6L, although the expansion opening col is illustrated to be formed only in a partial area of the inclined area SA (for example, an area closest to the periphery circuit area PCA), the embodiment is not limited thereto. For example, the expansion opening col may be formed throughout the inclined area SA, and in this case, the expansion opening col may have more expanded space as the expansion opening col is closer to the periphery circuit area PCA.

In some example embodiments, a portion of the lower protection layer 132 exposed through the expansion opening col may be partially removed.

Referring to FIGS. 6L and 6M, the plurality of word line trenches 120T may be formed by removing portions of the lower protection layer 132 and the substrate 110 by using the fourth sacrificial pattern pp4 as an etching mask. According to some example embodiments, the first word line trench 120T1 may be formed in a portion of the substrate 110 vertically overlapping the cell opening col, and the second word line trench 120T2 may be formed in a portion of the substrate 110 vertically overlapping the expansion opening col. In some example embodiments, the fourth sacrificial pattern pp4 may be removed in the process of forming the word line trench 120T. In some example embodiments, the active side saddle portion SDA (refer to FIG. 2C) and the dummy side saddle portion SDD (refer to FIG. 2C) may be exposed through the plurality of word line trenches 120T.

Referring to FIGS. 6M and 3D together, after removing the residual lower protection layer 132 from the resultant product of FIG. 5M, the gate dielectric layer 122, the gate electrode 124, the conductive layer 126, and the capping insulating layer 128 may be sequentially formed in the plurality of word line trenches 120T, and the main surface 110M of the substrate 110 may be exposed by performing a planarization process. Thereafter, a direct contact (not illustrated) and the bit line BL (refer to FIG. 2A) connected to the direct contact (not illustrated) may be formed in the plurality of active areas ACT, and a capacitor structure (not illustrated) may be arranged on the bit line BL and connected to the plurality of active areas ACT.

While various inventive concepts have been particularly shown and described with reference to example embodiments thereof, it will be understood that various changes in form and details may be made therein without departing from the spirit and scope of the following claims. Furthermore, example embodiments are not necessarily mutually exclusive with one another. For example, some example embodiments may include one or more features described with reference to one or more figures, and may also include one or more other features described with reference to one or more other figures.

What is claimed is:

1. An integrated circuit device comprising:
a substrate including a plurality of active areas and a plurality of dummy active areas,
the substrate defining a plurality of word line trenches that cross the plurality of active areas and the plurality of dummy active area, extend in a first horizontal direction in parallel with each other, and have an active side bottom surface exposing the plurality of active areas and a dummy side bottom surface exposing the plurality of dummy active areas,
wherein the dummy side bottom surface is at a lower vertical level than the active side bottom surface.

2. The integrated circuit device of claim 1, further comprising:
a plurality of gate electrodes respectively arranged at least partly in the plurality of word line trenches,
wherein the plurality of gate electrodes continuously extend in the first horizontal direction in the plurality of active areas and the plurality of dummy active areas.

3. The integrated circuit device of claim 1, further comprising:
a plurality of gate electrodes respectively arranged at least partly in the plurality of word line trenches and extending in the first horizontal direction in the plurality of active areas and the plurality of dummy active areas, wherein
a portion of each of the plurality of gate electrodes that at least partly overlaps the plurality of active areas has an active side width in a second horizontal direction perpendicular to the first horizontal direction,
a portion of each of the plurality of gate electrodes that at least partly overlaps the plurality of dummy active areas has a dummy side width in the second horizontal direction, and
the dummy side width is greater than the active side width.

4. The integrated circuit device of claim 1, further comprising:
a plurality of gate electrodes respectively arranged at least partly in the plurality of word line trenches and extending in the plurality of active areas and the plurality of dummy active areas in the first horizontal direction,
wherein an upper surface of a portion of the plurality of gate electrodes that at least partly overlaps the plurality of active areas is arranged at an identical vertical level to an upper surface of a portion of the plurality of gate electrodes that at least partly overlaps the plurality of dummy active areas.

5. The integrated circuit device of claim 1, wherein each of the plurality of dummy active areas comprises a portion that has a width in the first horizontal direction that is greater than a width of each of the plurality of active areas in the first horizontal direction.

6. The integrated circuit device of claim 1, wherein the plurality of dummy active areas comprise:
a first dummy active area selected from the plurality of dummy active areas and arranged adjacent to the plurality of active areas; and
a second dummy active area selected from the plurality of dummy active areas that is apart from the plurality of active areas in the first horizontal direction with the first dummy active area therebetween.

7. The integrated circuit device of claim 6, wherein
the dummy side bottom surface comprises a first dummy side bottom surface exposing the first dummy active area and a second dummy side bottom surface exposing the second dummy active area, and
the second dummy side bottom surface is at a lower vertical level than the first dummy side bottom surface.

8. The integrated circuit device of claim 1, wherein the plurality of word line trenches comprise:
a plurality of first word line trenches arranged along a second horizontal direction perpendicular to the first horizontal direction; and
a plurality of second word line trenches arranged on both sides of the plurality of first word line trenches in the second horizontal direction,
wherein bottom surfaces of the plurality of second word line trenches are at a lower vertical level than bottom surfaces of the plurality of first word line trenches.

9. The integrated circuit device of claim 8, further comprising:
a plurality of first word lines respectively arranged at least partly in the plurality of first word line trenches; and
a plurality of second word lines respectively arranged at least partly in the plurality of second word line trenches,
wherein a width in the second horizontal direction of a portion of the plurality of second word lines that at least partly overlaps the plurality of active areas is identical to a width in the second horizontal direction of a portion of the plurality of second word lines that at least partly overlaps the plurality of dummy active areas.

10. The integrated circuit device of claim 8, further comprising:
a plurality of first word lines respectively arranged at least partly in the plurality of first word line trenches; and
a plurality of second word lines respectively arranged at least partly in the plurality of second word line trenches,
wherein a width in the second horizontal direction of a portion of the plurality of first word lines that at least partly overlaps the plurality of active areas, is less than a width in the second horizontal direction of a portion of the plurality of second word lines that at least partly overlaps the plurality of active areas.

11. An integrated circuit device comprising:
a substrate including a plurality of fin-type active areas and a plurality of fin-type dummy active areas, defined by a device isolation layer,
the substrate defining a plurality of word line trenches that cross the plurality of fin-type active areas and the plurality of fin-type dummy active areas and extend in a first horizontal direction in parallel with each other, wherein
the plurality of fin-type active areas comprise active side saddle portions exposed on bottom surfaces of the plurality of word line trenches,
the plurality of fin-type dummy active areas comprise dummy side saddle portions exposed on bottom surfaces of the plurality of word line trenches, and
an upper surface of the dummy side saddle portions is at a lower vertical level than an upper surface of the active side saddle portions.

12. The integrated circuit device of claim 11, further comprising:
a gate dielectric layer that covers inner walls of the plurality of word line trenches;
a gate electrode that at least partly fills a portion of the plurality of word line trenches on the gate dielectric layer;
a conductive layer that at least partly fills a portion of the plurality of word line trenches on the gate electrode; and
a capping insulating layer that at least partly fills remaining portions of the plurality of word line trenches on the conductive layer.

13. The integrated circuit device of claim 12, wherein the gate electrode continuously extends in a first horizontal direction in the plurality of fin-type active areas and the plurality of fin-type dummy active areas without disconnection.

14. The integrated circuit device of claim 11, further comprising:
a plurality of gate electrodes respectively arranged in the plurality of word line trenches and extending in the first horizontal direction in the plurality of fin-type active areas and the plurality of fin-type dummy active areas, wherein
a portion of the plurality of gate electrodes that at least partly overlaps the plurality of fin-type active areas and has an active side width in a second horizontal direction perpendicular to the first horizontal direction,
a portion of the plurality of gate electrodes that at least partly overlaps the plurality of fin-type dummy active areas and has a dummy side width in the second horizontal direction, and
the dummy side width is greater than the active side width.

15. The integrated circuit device of claim 14, wherein an upper surface of a portion of the plurality of gate electrodes that at least partly overlaps the plurality of fin-type active areas is at an identical vertical level to an upper surface of a portion of the plurality of gate electrodes that at least partly overlaps the plurality of fin-type dummy active areas.

16. The integrated circuit device of claim 11, wherein the plurality of fin-type dummy active areas comprise:
a first fin-type dummy active area selected from the plurality of fin-type dummy active areas and arranged adjacent to the plurality of fin-type active areas; and
a second fin-type dummy active area selected from the plurality of fin-type dummy active areas that is apart from the plurality of fin-type active areas in the first horizontal direction with the first fin-type dummy active area therebetween, wherein
the dummy side saddle portion comprises a first dummy side saddle portion in which the first fin-type dummy active area is exposed through bottom surfaces of the plurality of word line trenches, and a second dummy side saddle portion in which the second fin-type dummy active area is exposed through bottom surfaces of the plurality of word line trenches, and
an upper surface of the second dummy side saddle portion is at a lower vertical level than an upper surface of the first dummy side saddle portion.

17. The integrated circuit device of claim 11, wherein the plurality of word line trenches comprise:
a plurality of first word line trenches arranged along a second horizontal direction perpendicular to the first horizontal direction; and
a plurality of second word line trenches arranged on first and second sides of the plurality of first word line trenches in the second horizontal direction,
wherein bottom surfaces of the plurality of second word line trenches are at a lower vertical level than bottom surfaces of the plurality of first word line trenches.

18. An integrated circuit device comprising:
a substrate including a plurality of dummy active areas and a plurality of dummy active areas, defined by a device isolation layer,
the substrate defining a plurality of word line trenches cross the plurality of active areas and the plurality of dummy active area, extend in a first horizontal direction in parallel with each other, and have an active side bottom surface exposing the plurality of active areas, and a dummy side bottom surface exposing the plurality of dummy active areas at a lower vertical level than the active side bottom surface; and
a plurality of gate electrodes respectively at least partly in the plurality of word line trenches and extending in the plurality of active areas and the plurality of dummy active areas in the first horizontal direction, wherein
a portion of the plurality of gate electrodes that at least partly overlaps the plurality of active areas has an active side width in a second horizontal direction perpendicular to the first horizontal direction,
a portion of the plurality of gate electrodes that at least partly overlaps the plurality of dummy active areas has a dummy side width in the second horizontal direction, and
the dummy side width is greater than the active side width.

19. The integrated circuit device of claim 18, wherein an upper surface of a portion of the plurality of gate electrodes that at least partly overlaps the plurality of active areas is at an identical vertical level to an upper surface of a portion of the plurality of gate electrodes that at least partly overlaps the plurality of dummy active areas.

20. The integrated circuit device of claim 19, wherein the plurality of word line trenches comprise,
a plurality of first word line trenches arranged along a second horizontal direction perpendicular to the first horizontal direction, and
a plurality of second word line trenches arranged on both sides of the plurality of first word line trenches in the second horizontal direction,
wherein the plurality of gate electrodes comprise,
a plurality of first word lines respectively arranged in the plurality of first word line trenches and
a plurality of second word lines respectively arranged in the plurality of second word line trenches, wherein
bottom surfaces of the plurality of second word line trenches are at a lower vertical level than bottom surfaces of the plurality of first word line trenches, and
a width in the second horizontal direction of a portion of the plurality of second word lines that overlaps the plurality of active areas, is identical to a width in the second horizontal direction of a portion of the plurality of second word lines that overlaps the plurality of dummy active areas.
